(19) United States
(12) Patent Application Publication
(10) Pub. No.: US 2010/0180429 A1
(43) Pub. Date: Jul. 22, 2010

(54) CARBON NANOTUBE HEATER

(75) Inventors: Chen FENG, Beijing (CN); Kai LIU, Beijing (CN); Jia-Ping WANG, Beijing (CN); Kai-Li JIANG, Beijing (CN); Chang-Hong LIU, Beijing (CN); Shou-Shan FAN, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: TSINGHUA UNIVERSITY, Beijing (CN); HON HAI PRECISION INDUSTRY CO., LTD., Tu-Cheng (TW)

(21) Appl. No.: 12/750,186

(22) Filed: Mar. 30, 2010

Related U.S. Application Data
(63) Continuation of application No. 12/655,507, filed on Dec. 31, 2009.

(30) Foreign Application Priority Data
Jun. 13, 2008 (CN) 200810067731.2
Jun. 18, 2008 (CN) 200810067904.0
Jun. 27, 2008 (CN) 200810068069.2
Jun. 27, 2008 (CN) 200810068070.5
Jun. 27, 2008 (CN) 200810068076.2
Jun. 27, 2008 (CN) 200810068077.7
Jun. 27, 2008 (CN) 200810068078.1
Jul. 11, 2008 (CN) 200810068458.5
Jul. 11, 2008 (CN) 200810068459.X
Jul. 11, 2008 (CN) 200810068461.7
Jul. 11, 2008 (CN) 200810068462.1
Jul. 25, 2008 (CN) 200810142522.X
Jul. 25, 2008 (CN) 200810142526.8
Jul. 25, 2008 (CN) 200810142527.2
Jul. 25, 2008 (CN) 200810142528.7
Jul. 25, 2008 (CN) 200810142529.1
Jul. 25, 2008 (CN) 200810142610.X
Jul. 25, 2008 (CN) 200810142614.8
Jul. 25, 2008 (CN) 200810142615.2
Jul. 25, 2008 (CN) 200810142616.7
Jul. 25, 2008 (CN) 200810142617.1
Apr. 20, 2009 (CN) 200910106599.6
Apr. 20, 2009 (CN) 200910106600.5
Apr. 20, 2009 (CN) 200910106802.X
Apr. 20, 2009 (CN) 200910106803.4
Apr. 20, 2009 (CN) 200910106804.9
Apr. 20, 2009 (CN) 200910106805.3
Apr. 20, 2009 (CN) 200910106806.8
Apr. 20, 2009 (CN) 200910106807.2
Apr. 20, 2009 (CN) 200910106808.7
Apr. 20, 2009 (CN) 200910106809.1
Apr. 20, 2009 (CN) 200910106810.4
Apr. 20, 2009 (CN) 200910106811.9
Apr. 20, 2009 (CN) 200910106812.3
Apr. 20, 2009 (CN) 200910106813.8
Apr. 20, 2009 (CN) 200910106814.2

(51) Int. Cl. H05K 13/00

(52) U.S. Cl. 29/592.1

(57) ABSTRACT

A method for making a planar heater is provided. A first electrode and a second electrode are connected to a carbon nanotube structure having a plurality of micropores. The carbon nanotube structure is fixed on a surface of a planar supporter. A material is supplied into the carbon nanotube structure to achieve a carbon nanotube composite structure.

### RELATED APPLICATIONS

This application is a continuation application of U.S. patent application Ser. No. 12/655,507, filed Dec. 31, 2009 entitled “CARBON NANOTUBE HEATER” the disclosure of which is incorporated by reference.

### BACKGROUND

1. Technical Field

The present disclosure generally relates to heaters based on carbon nanotubes.

2. Description of Related Art

Heaters are configured for generating heat. According to the structures, the heaters can be divided into three types: linear heater, planar heater and hollow heater.

The linear heater has a linear structure, and is a one-dimensional structure. An object to be heated can be wrapped by the linear heater when the linear heater is used to heat the object. The linear heater has an advantage of being very small in size and can be used in appropriate applications.

The planar heater has a planar two-dimensional structure. An object to be heated is placed near the planar structure and heated. The planar heater provides a wide planar heating surface and an even heating to an object. The planar heater has been widely used in various applications such as infrared therapeutic instruments, electric heaters, etc.

The hollow heater defines a hollow space therein, and is three-dimensional structure. An object to be heated can be placed in the hollow space of the hollow heater. The hollow heater can apply heat in different directions about an object and will have a high heating efficiency. Hollow heaters have been widely used in various applications.

A typical heater includes a heating element and at least two electrodes. The heating element is located on the two electrodes. The heating element generates heat when a voltage is applied to it. The heating element is often made of metal such as tungsten. Metals, which have good conductivity, can generate a lot of heat even when a low voltage is applied. However, metals may be easily oxidized, thus the heater element has a short life. Furthermore, since metals have a relative high density, the heating element made of metals are heavy, which limits applications of such heater.

What is needed, therefore, is a heater based on carbon nanotubes that can overcome the above-described shortcomings.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isotropic view of one embodiment of a planar heater having a carbon nanotube structure.

FIG. 2 is a schematic, cross-sectional view, along a line 2-2 of FIG. 1.

FIG. 3 is a Scanning Electron Microscope (SEM) image of a drawn carbon nanotube film.

FIG. 4 is a schematic view of a carbon nanotube segment in the drawn carbon nanotube film of FIG. 3.

FIG. 5 is an SEM image of a flocculated carbon nanotube film.

FIG. 6 is an SEM image of a pressed carbon nanotube film.

FIG. 7 is an SEM image of an untwisted carbon nanotube wire.

FIG. 8 is an SEM image of a twisted carbon nanotube wire.

FIG. 9 is a schematic view of one embodiment of an untwisted linear carbon nanotube structure.

FIG. 10 is a schematic view of one embodiment of a twisted linear carbon nanotube structure.

FIG. 11 is a schematic view of a planar heater, wherein the heating element is a single linear carbon nanotube structure.

FIG. 12 is a schematic view of a planar heater, wherein the heating element includes a plurality of parallel linear carbon nanotube structures.

FIG. 13 is a schematic view of a planar heater, wherein the heating element includes a plurality of woven linear carbon nanotube structures.

FIG. 14 is a schematic view of a planar heater, wherein the heating element includes a plurality of spaced carbon nanotube structures.

FIG. 15 is an SEM image of a fracture surface of one embodiment of the heating element.

FIG. 16 is a schematic, cross-sectional view of one embodiment of a planar heater having a carbon nanotube structure.

FIG. 17 is a relationship of one embodiment of temperature and time of a planar heater.

FIG. 18 is a flow chart of a method of one embodiment for fabricating a planar heater.

FIG. 19 is an isotropic view of one embodiment of a hollow heater having a carbon nanotube structure.

FIG. 20 is a schematic, cross-sectional view, along a line 20-20 of FIG. 19.

FIG. 21 is a schematic, cross-sectional view, of one embodiment of a hollow heater.

FIG. 22 is a schematic, cross-sectional view, of one embodiment of a hollow heater.

FIG. 23 is an isotropic view of a hollow heater, wherein the heating element is a single linear carbon nanotube structure.

FIG. 24 is an isotropic view of a hollow heater, wherein the heating element includes a plurality of parallel linear carbon nanotube structures.

FIG. 25 is an isotropic view of a hollow heater, wherein the heating element includes a plurality of woven linear carbon nanotube structures.

FIG. 26 is an isotropic view of one embodiment of a hollow heater.

FIG. 27 is an isotropic view of one embodiment of a hollow heater.

FIG. 28 is a flow chart of a method of one embodiment for fabricating a hollow heater.

FIG. 29 is an isotropic view of other embodiment of a hollow heater having a carbon nanotube structure.

FIG. 30 is a schematic, cross-sectional view, along a line 30-30 of FIG. 29.

FIG. 31 is a schematic, cross-sectional view, along a line 31-31 of FIG. 29.

FIG. 31a is a schematic, cross-sectional view of other embodiment of a hollow heater having a carbon nanotube structure.

FIG. 32 is an isotropic view of other embodiments of a hollow heater having a carbon nanotube structure.

FIG. 33 is a schematic, cross-sectional view, along a line 33-33 of FIG. 32.

FIG. 34 is an isotropic view of one embodiment of a linear heater having a carbon nanotube structure.

FIG. 35 is a schematic, cross-sectional view, along a line 35-35 of FIG. 34.

FIG. 36 is a schematic, cross-sectional view, along a line 36-36 of FIG. 35.

FIG. 37 is an isotropic view of other embodiment of a linear heater having a carbon nanotube structure.

FIG. 38 is a flow chart of a method of one embodiment for fabricating a linear heater.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

The present disclose presents several illustrative embodiments of the heater. The heaters of these illustrative embodiments are generally divided into three types: planar heater, hollow heater and linear heater.

### Planar Heater

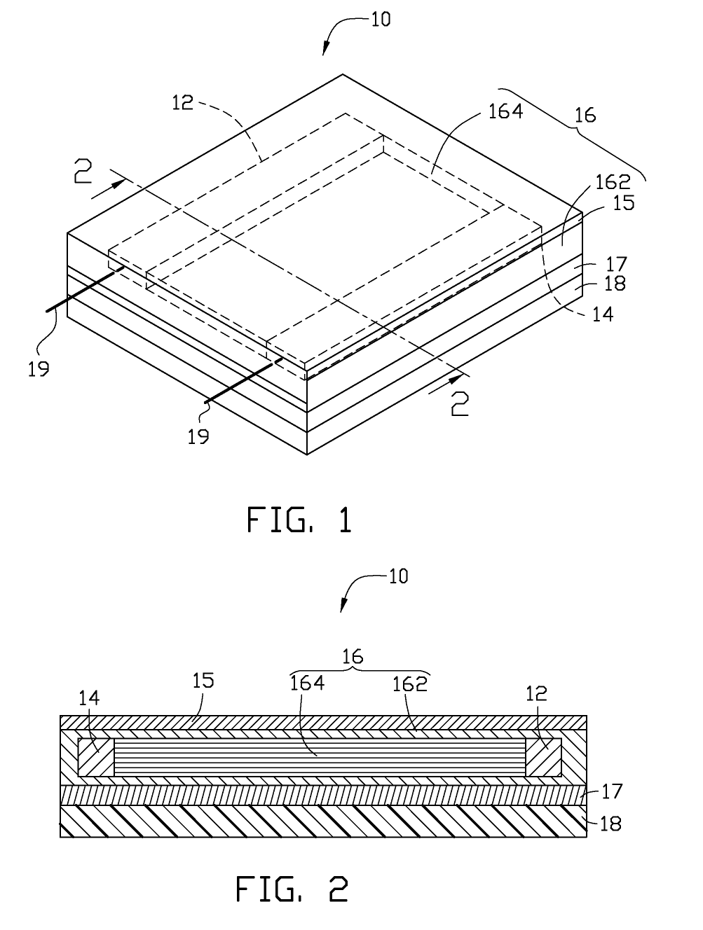

Referring to FIGS. 1 and 2, a planar heater 10 of one embodiment is shown. The planar heater 10 includes a planar supporter 18, a heat-reflecting layer 17, a heating element 16, a first electrode 12, a second electrode 14, and a protecting layer 15. Two wires 19 are connected to the first and second electrodes 12, 14 to supply a power to the planar heater 10. The heat-reflecting layer 17 is disposed on a top surface of the planar supporter 18. The heating element 16 is disposed on a top surface of the heat-reflecting layer 17. The first electrode 12 and the second electrode 14 are located within the heating element 16 and electrically connected to the heating element 16. The protecting layer 15 is disposed on a top surface of the heating element 16. In other embodiments, the first electrode 12 and the second electrode 14 are located on a top surface of the heating element 16 and spaced apart from each other.

The planar supporter 18 is configured to support the heating element 16 and the heat-reflecting layer 17. The planar supporter 18 is made of flexible materials or rigid materials. The flexible materials may be plastics, resins or fibers. The rigid materials may be ceramics, glasses, or quartzes. When the flexible materials are used, the planar heater 10 can be bent to desired shape according to practical needs. The shape and size of the planar supporter 18 can be determined according to practical needs. For example, the planar supporter 18 may be square, round or triangular. In one embodiment, the planar supporter 18 is a square ceramic sheet about 1 millimeter (mm) thick. It should be noted that the planar supporter 18 is optional. The heating element 16 can be a free standing structure without the need of support from the planar supporter 18.

The heat-reflecting layer 17 is configured to reflect back the heat emitted by the heating element 16, and configured for controlling the direction of the heat emitted by the heating element 16 for single-side heating. The heat-reflecting layer 17 may be made of insulative materials. The material of the heat-reflecting layer 17 can be selected from metal oxides, metal salts, or ceramics. In one embodiment, the heat-reflecting layer 17 is an aluminum oxide (Al₂O₃) film. The thickness of the heat-reflecting layer 17 can be in a range from about 100 micrometer (μm) to about 0.5 mm. In one embodiment, the thickness of the heat-reflecting layer 17 is about 0.1 mm. The heat-reflecting layer 17 can be sandwiched between the heating element 16 and the planar supporter 18. Alternatively, the heat-reflecting layer 17 can be omitted, and the heating element 16 can be located directly on the planar supporter 18 if desired. In other embodiments, the heating element 16 can be free standing without being attached to either a planar supporter 18 or a heat-reflecting layer 17. When there is no heat-reflecting layer, the planar heater 10 can be used for double-side heating as shown in FIG. 16.

With reference primarily to FIG. 2, the heating element 16 can be a carbon nanotube composite structure. The carbon nanotube composite structure includes a matrix 162 and one or more carbon nanotube structures 164. The matrix 162 encloses the entire carbon nanotube structure 164 therein. Alternatively, the carbon nanotube structure 164 includes a plurality of micropores and the matrix 162 is dispersed or permeated in the micropores of the carbon nanotube structure 164. The heating element 16 can be a layer-shape structure such as planar or have a camber. In one embodiment shown in FIGS. 1-2, the heating element 16 is a rectangular plate with the carbon nanotube structure 164 entirely enclosed within the matrix 162.

The carbon nanotube structure 164 can be a free-standing structure, that is, the carbon nanotube structure 164 can be supported by itself and does not need a substrate to lay on and supported thereby. When someone holding at least a point of the carbon nanotube structure, the entire carbon nanotube structure can be lift without destroyed. The carbon nanotube structure 164 includes a plurality of carbon nanotubes combined by van der Waals attractive force therebetween. The carbon nanotube structure 164 can be a substantially pure structure of the carbon nanotubes, with few impurities. The carbon nanotubes can be used to form many different structures and provide a large specific surface area. The heat capacity per unit area of the carbon nanotube structure 164 can be less than 2×10⁻⁴ J/m²*K. In one embodiment, the heat capacity per unit area of the carbon nanotube structure 164 is less than or equal to 1.7×10⁻⁶ J/m²*K. As the heat capacity of the carbon nanotube structure 164 is very low, and the temperature of the heating element 16 can rise and fall quickly, which makes the heating element 16 have a high heating efficiency and accuracy. As the carbon nanotube structure 164 can be substantially pure, the carbon nanotubes are not easily oxidized and the lifespan of the heating element 16 will be relatively longer. Further, the carbon nanotubes have a low density, about 1.35 g/cm³, so the heating element 16 is light. As the heat capacity of the carbon nanotube structure 164 is very low, the heating element 16 has a high response heating speed. As the carbon nanotube has large specific surface area, the carbon nanotube structure 164 with a plurality of carbon nanotubes has large specific surface area. When the specific surface of the carbon nanotube structure 164 is large enough, the carbon nanotube structure 164 is adhesive and can be directly applied to a surface.

The carbon nanotubes in the carbon nanotube structure 164 can be arranged orderly or disorderly. The term ‘disordered carbon nanotube structure’ refers to a structure where the carbon nanotubes are arranged along different directions, and the aligning directions of the carbon nanotubes are random. The number of the carbon nanotubes arranged along each different direction can be almost the same (e.g. uniformly disordered). The disordered carbon nanotube structure can be isotropic, namely the carbon nanotube film has properties identical in all directions of the carbon nanotube film. The carbon nanotubes in the disordered carbon nanotube structure can be entangled with each other.

The carbon nanotube structure 164 including ordered carbon nanotubes is an ordered carbon nanotube structure. The term ‘ordered carbon nanotube structure’ refers to a structure where the carbon nanotubes are arranged in a consistently systematic manner, e.g., the carbon nanotubes are arranged approximately along a same direction and/or have two or more sections within each of which the carbon nanotubes are arranged approximately along a same direction (different sections can have different directions). The carbon nanotubes in the carbon nanotube structure 164 can be selected from single-walled, double-walled, and/or multi-walled carbon nanotubes.

The carbon nanotube structure 164 can be a carbon nanotube film structure with a thickness ranging from about 0.5 nanometers (nm) to about 1 mm. The carbon nanotube film structure can include at least one carbon nanotube film. The carbon nanotube structure 164 can also be at least one linear carbon nanotube structure with a diameter ranging from about 0.5 nm to about 1 mm. The carbon nanotube structure 164 can also be a combination of the carbon nanotube film structure and the linear carbon nanotube structure. It is understood that any carbon nanotube structure 164 described can be used with all embodiments. It is also understood that any carbon nanotube structure 164 may or may not employ a support structure.

Carbon Nanotube Film Structure

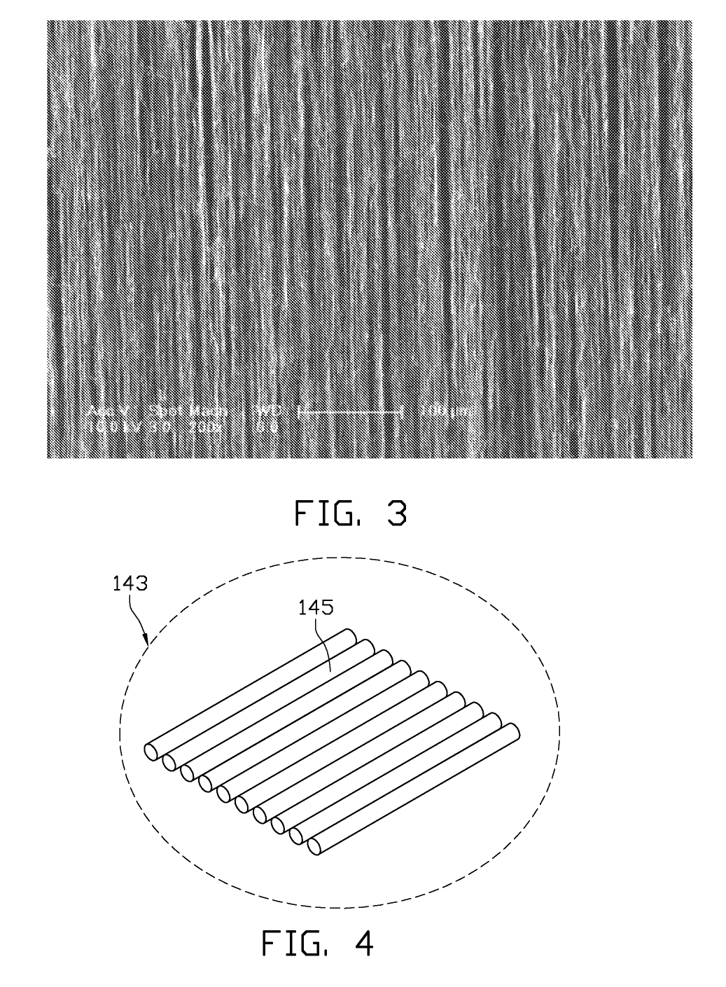

In one embodiment, the carbon nanotube film structure includes at least one drawn carbon nanotube film. A film can be drawn from a carbon nanotube array, to obtain a drawn carbon nanotube film. Examples of drawn carbon nanotube film are taught by U.S. Pat. No. 7,045,108 to Jiang et al., and WO 2007015710 to Zhang et al. The drawn carbon nanotube film includes a plurality of successive and oriented carbon nanotubes joined end-to-end by van der Waals attractive force therebetween. The drawn carbon nanotube film is a free-standing film. Referring to FIGS. 3 to 4, each drawn carbon nanotube film includes a plurality of successively oriented carbon nanotube segments 143 joined end-to-end by van der Waals attractive force therebetween. Each carbon nanotube segment 143 includes a plurality of carbon nanotubes 145 parallel to each other, and combined by van der Waals attractive force therebetween. As can be seen in FIG. 3, some variations can occur in the drawn carbon nanotube film. The carbon nanotubes 145 in the drawn carbon nanotube film are oriented along a preferred orientation. The carbon nanotube film can be treated with an organic solvent to increase the mechanical strength and toughness of the carbon nanotube film and reduce the coefficient of friction of the carbon nanotube film. The thickness of the carbon nanotube film can range from about 0.5 nm to about 100 μm.

The carbon nanotube film structure of the heating element 16 can include at least two stacked carbon nanotube films. In other embodiments, the carbon nanotube structure can include two or more coplanar carbon nanotube films, and can include layers of coplanar carbon nanotube films. Additionally, when the carbon nanotubes in the carbon nanotube film are aligned along one preferred orientation (e.g., the drawn carbon nanotube film), an angle can exist between the orientations of carbon nanotubes in adjacent films, whether stacked or adjacent. Adjacent carbon nanotube films can be combined by only the van der Waals attractive force therebetween. The number of the layers of the carbon nanotube films is not limited. However, the thicker the carbon nanotube structure, the specific surface area will decrease. An angle between the aligned directions of the carbon nanotubes in two adjacent carbon nanotube films can range from about 0 degrees to about 90 degrees. When the angle between the aligned directions of the carbon nanotubes in adjacent carbon nanotube films is larger than 0 degrees, a microporous structure is defined by the carbon nanotubes in the heating element 16. The carbon nanotube structure in an embodiment employing these films will have a plurality of micropores. Stacking the carbon nanotube films will also add to the structural integrity of the carbon nanotube structure.

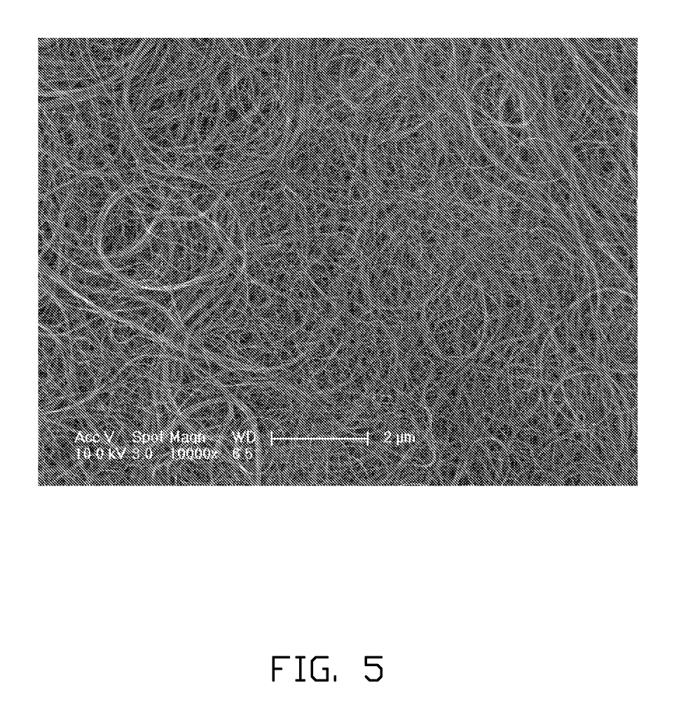

In other embodiments, the carbon nanotube film structure includes a flocculated carbon nanotube film. Referring to FIG. 5, the flocculated carbon nanotube film can include a plurality of long, curved, disordered carbon nanotubes entangled with each other. Further, the flocculated carbon nanotube film can be isotropic. The carbon nanotubes can be substantially uniformly dispersed in the carbon nanotube film. Adjacent carbon nanotubes are acted upon by van der Waals attractive force to obtain an entangled structure with micropores defined therein. It is understood that the flocculated carbon nanotube film is very porous. Sizes of the micropores can be less than 10 μm. The porous nature of the flocculated carbon nanotube film will increase specific surface area of the carbon nanotube structure. Further, due to the carbon nanotubes in the carbon nanotube structure being entangled with each other, the carbon nanotube structure employing the flocculated carbon nanotube film has excellent durability, and can be fashioned into desired shapes with a low risk to the integrity of the carbon nanotube structure. The flocculated carbon nanotube film, in some embodiments, will not require the use of the planar supporter 18 due to the carbon nanotubes being entangled and adhered together by van der Waals attractive force therebetween. The thickness of the flocculated carbon nanotube film can range from about 0.5 nm to about 1 mm.

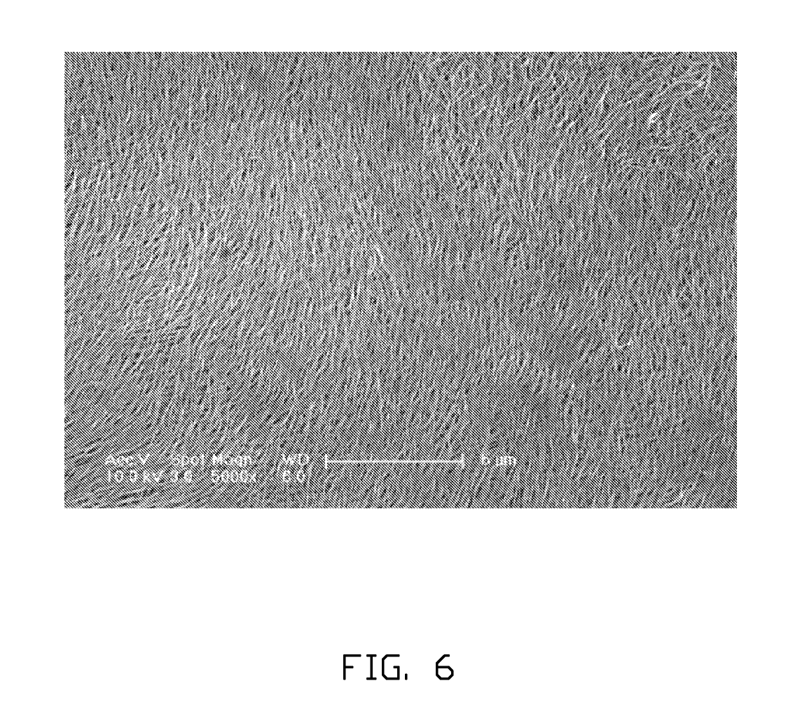

In other embodiments, the carbon nanotube film structure can include at least a pressed carbon nanotube film. Referring to FIG. 6, the pressed carbon nanotube film can be a free-standing carbon nanotube film. The carbon nanotubes in the pressed carbon nanotube film are arranged along a same direction or along different directions. The carbon nanotubes in the pressed carbon nanotube film can rest upon each other. Adjacent carbon nanotubes are attracted to each other and combined by van der Waals attractive force. An angle between a primary alignment direction of the carbon nanotubes and a surface of the pressed carbon nanotube film is about 0 degrees to approximately 15 degrees. The greater the pressure applied, the smaller the angle obtained. When the carbon nanotubes in the pressed carbon nanotube film are arranged along different directions, the carbon nanotube structure can be isotropic. Here, “isotropic” means the carbon nanotube film has properties identical in all directions parallel to a surface of the carbon nanotube film. The thickness of the pressed carbon nanotube film ranges from about 0.5 nm to about 1 mm. Examples of pressed carbon nanotube film are taught by US PGPub. 20080299031A1 to Liu et al.

Linear Carbon Nanotube Structure

In other embodiments, the linear carbon nanotube structure includes carbon nanotube wires and/or linear carbon nanotube structures.

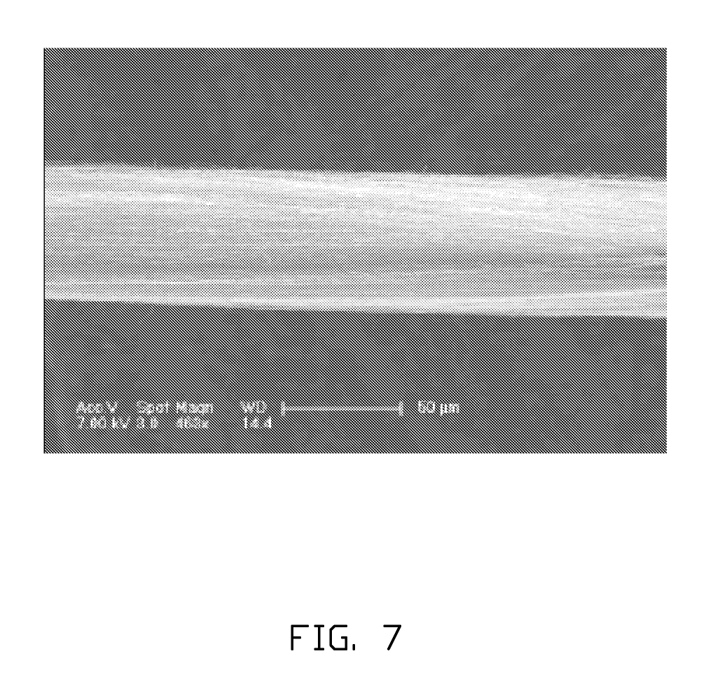

The carbon nanotube wire can be untwisted or twisted. Treating the drawn carbon nanotube film with a volatile organic solvent can obtain the untwisted carbon nanotube wire. In one embodiment, the organic solvent is applied to soak the entire surface of the drawn carbon nanotube film. During the soaking, adjacent parallel carbon nanotubes in the drawn carbon nanotube film will bundle together, due to the surface tension of the organic solvent as it volatilizes, and thus, the drawn carbon nanotube film will be shrunk into an untwisted carbon nanotube wire. Referring to FIG. 7, the untwisted carbon nanotube wire includes a plurality of carbon nanotubes substantially oriented along a same direction (i.e., a direction along the length direction of the untwisted carbon nanotube wire). The carbon nanotubes are parallel to the axis of the untwisted carbon nanotube wire. In one embodiment, the untwisted carbon nanotube wire includes a plurality of successive carbon nanotube segments joined end to end by van der Waals attractive force therebetween. Each carbon nanotube segment includes a plurality of carbon nanotubes substantially parallel to each other, and combined by van der Waals attractive force therebetween. The carbon nanotube segments can vary in width, thickness, uniformity and shape. Length of the untwisted carbon nanotube wire can be arbitrarily set as desired. A diameter of the untwisted carbon nanotube wire ranges from about 0.5 nm to about 100 μm.

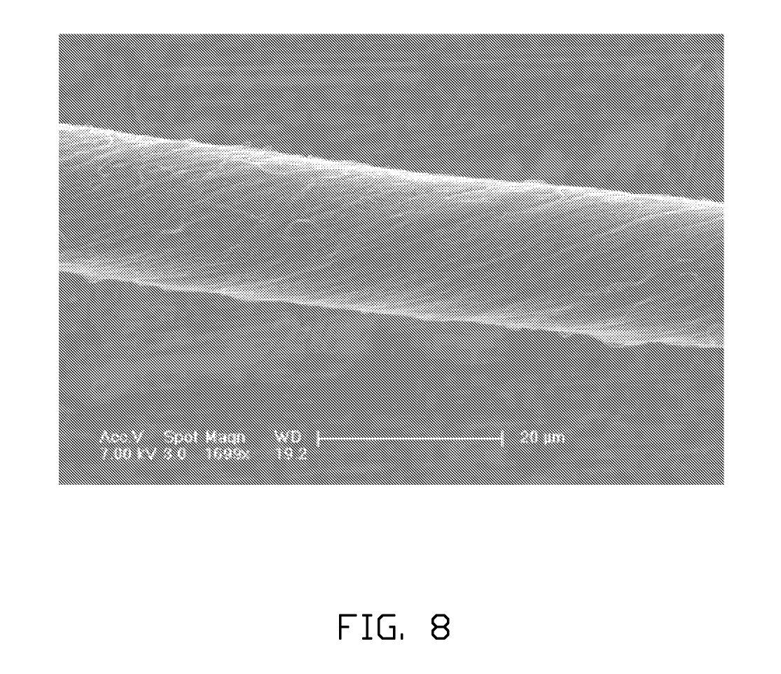

The twisted carbon nanotube wire can be obtained by twisting a drawn carbon nanotube film using a mechanical force to turn the two ends of the drawn carbon nanotube film in opposite directions. Referring to FIG. 8, the twisted carbon nanotube wire includes a plurality of carbon nanotubes helically oriented around an axial direction of the twisted carbon nanotube wire. In one embodiment, the twisted carbon nanotube wire includes a plurality of successive carbon nanotube segments joined end to end by van der Waals attractive force therebetween. Each carbon nanotube segment includes a plurality of carbon nanotubes substantially parallel to each other, and combined by van der Waals attractive force therebetween. Length of the carbon nanotube wire can be set as desired. A diameter of the twisted carbon nanotube wire can be from about 0.5 nm to about 100 μm. Further, the twisted carbon nanotube wire can be treated with a volatile organic solvent after being twisted. After being soaked by the organic solvent, the adjacent paralleled carbon nanotubes in the twisted carbon nanotube wire will bundle together, due to the surface tension of the organic solvent when the organic solvent volatilizing. The specific surface area of the twisted carbon nanotube wire will decrease, while the density and strength of the twisted carbon nanotube wire will be increased.

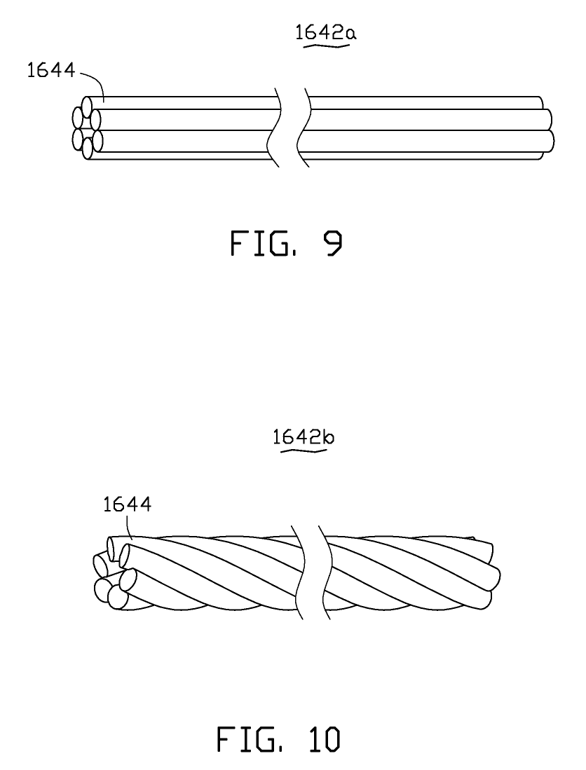

The linear carbon nanotube structure can include one or more carbon nanotube wires. The carbon nanotube wires in the linear carbon nanotube structure can be, twisted and/or untwisted. Referring to FIG. 9, in an untwisted linear carbon nanotube structure 1642a, the carbon nanotube wires 1644 are parallel with each other, and the axes of the nanotube wires 1644 extend along a same direction. Referring to FIG. 10, in a twisted linear carbon nanotube structure 1642b, carbon nanotube wires 1644 are twisted with each other.

The matrix 162 can be made of a material being selected from polymer, inorganic non-metal or combinations thereof. The material or the precursor of the matrix 162 can be liquid or gas at a certain temperature so that the material or the precursor of the matrix 162 can infiltrate into the micropores of the carbon nanotube structure 164 during the process of making the heating element 16. The matrix 162 has good thermal stability and is not easy to be distorted, melted and decomposed under the working temperature of the planar heater 10.

Examples of available polymers are cellulose, polyethylene, polypropylene, polystyrene, polyvinyl chloride (PVC), epoxy resin, phenol formaldehyde resin, silica gel, polyester, polyethylene terephthalate (PET), polymethyl methacrylate (PMMA) and combinations thereof. Examples of inorganic non-metal are glass, ceramic, semiconductor and combinations thereof.

The matrix 162 and the carbon nanotube structure 164 can form a layer-shaped carbon nanotube composite structure, a linear carbon nanotube composite structure or combinations thereof.

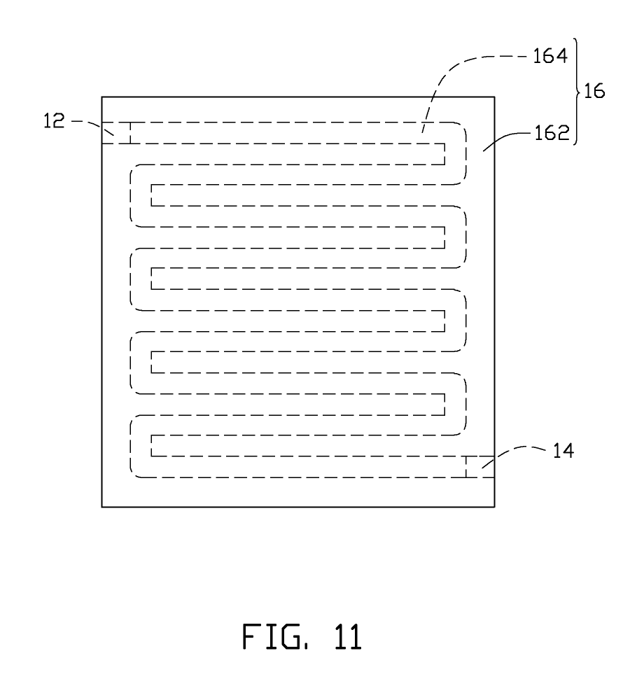

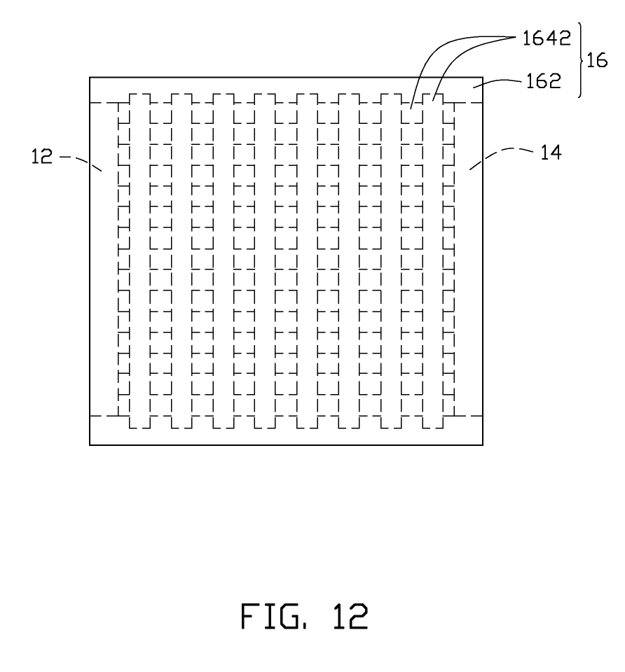

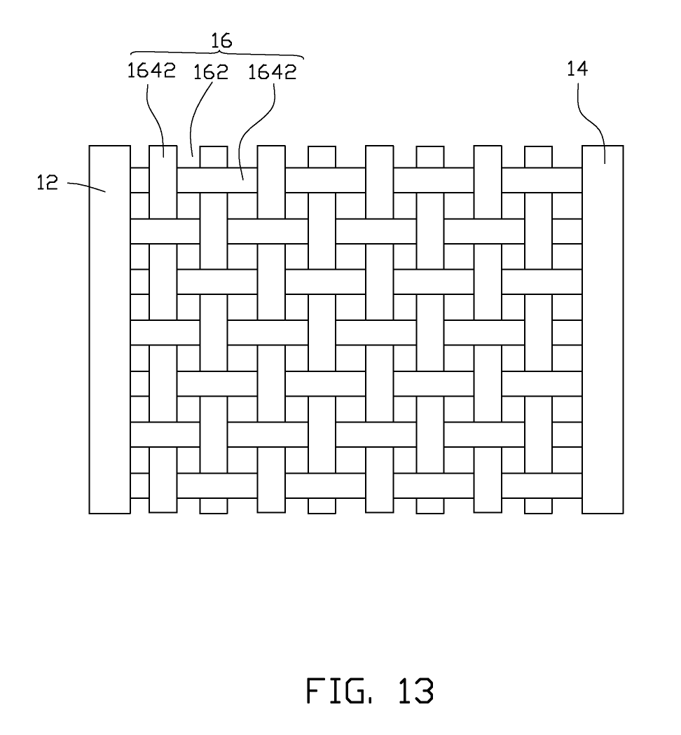

The layer-shaped carbon nanotube composite structure can include a matrix and a layer-shaped carbon nanotube structure having a plurality of micropores. In one example, the matrix is dispersed in the micropores of the layer-shaped carbon nanotube structure. In another example, the layer-shaped carbon nanotube structure is enclosed within in a layer-shape matrix. The layer-shaped carbon nanotube structure can be a plurality of carbon nanotube film structure stacked with each other. When the layer-shaped carbon nanotube structure includes a single linear carbon nanotube structure 1642, the single linear carbon nanotube structure 1642 can be folded to obtain a layer-shape structure as shown in FIG. 11. When the layer-shaped carbon nanotube structure includes a plurality of linear carbon nanotube structures 1642, the linear carbon nanotube structures 1642 can be paralleled with each other (not shown), crossed with each other as shown in FIG. 12 or weaved together as shown in FIG. 13 to obtain a layer-shape structure.

The linear carbon nanotube composite structure can include a matrix and a linear carbon nanotube structure having a plurality of micropores. In one example, the linear carbon nanotube structure is enclosed within the linear matrix. In another example, the matrix is dispersed in the micropores of the linear carbon nanotube structure. A single linear carbon nanotube composite structure can be folded to obtain a layer-shape heating element 16. A plurality of linear carbon nanotube composite structures can be paralleled with each other, crossed with each other or weaved together to obtain a layer-shape heating element 16.

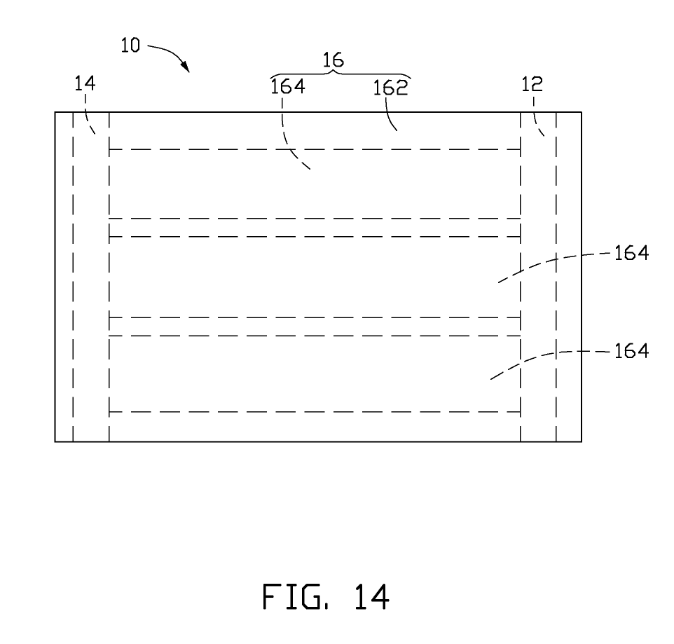

Referring to FIG. 14, the heating element 16 can include a plurality of planar carbon nanotube structures 164 separately located in the matrix 162. The planar carbon nanotube structures 164 are parallel arranged between the first electrode 12 and the second electrode 14. This structure allows the heating element 16 to have different heating temperature in different locations. Furthermore, this structure lower the amount of carbon nanotubes used in fabricating the heating element 16.

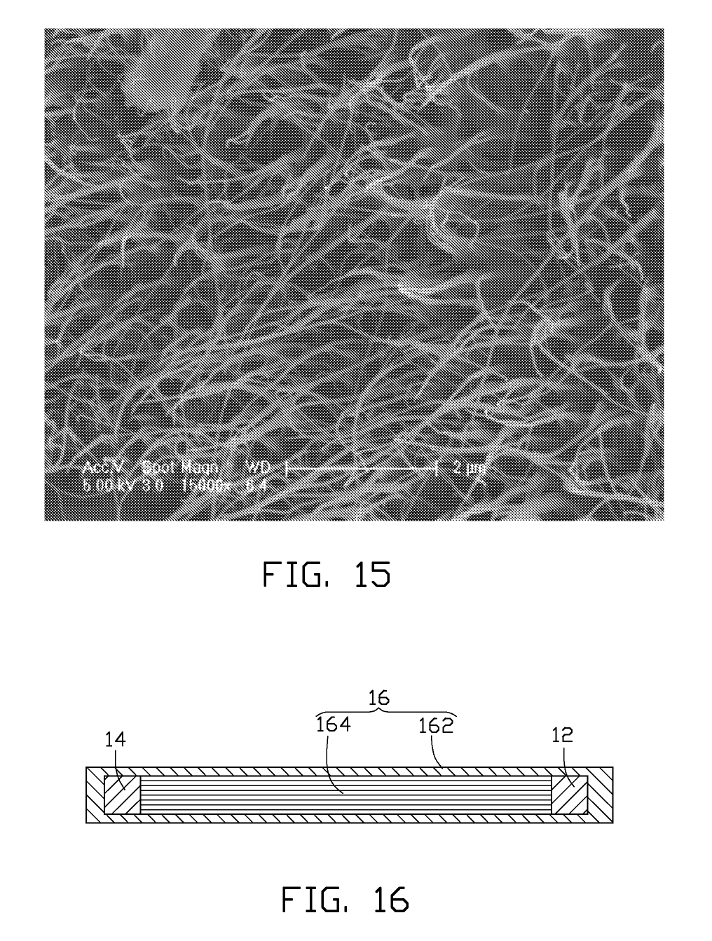

In one embodiment, a heating element 16, comprising drawn carbon nanotube film and epoxy resin, is broken by pulling along the aligned directions of the carbon nanotubes. Referring to FIG. 15, it shows an enlarged view of a fracture surface of the heating element and shows that the carbon nanotubes in heating element are still oriented along a preferred orientation after forming a carbon nanotube composite structure with epoxy resin. Then, the first electrode 12 and the second electrode 14 are attached to the broken position and electrically connected to the drawn carbon nanotube film in the epoxy resin matrix after tearing.

The matrix 162 in the micropores of the carbon nanotube structure 164 can combine the carbon nanotubes of the carbon nanotube structure 164 and prevent the carbon nanotubes from separating. When the entire carbon nanotube structure 164 is enclosed within the matrix 162, the matrix 162 can protect the carbon nanotube structure 164 from outside contaminants. When the material of the matrix 162 is insulative, the matrix 162 can electrically insulate the carbon nanotube structure 164 from the external environment. The matrix 162 allows the heat in the heating element 16 to be dispersed uniformly. The matrix 162 can further slow down the temperature changing speed of the heating element 16. When the matrix 162 is made of flexible polymer, the flexibility of the heating element 16 can be improved.

The heating element 16 can be fabricated by combining the free standing carbon nanotube structure 164 with the matrix 162 directly. Because the carbon nanotubes can be uniformly dispersed in the matrix 162 and form a free standing structure, the weight percentage of the carbon nanotubes in the heating element 16 can be as high 99% in the composite structure. The greater the weight percentage of the carbon nanotubes in the heating element 16, the greater the heating temperature for a given voltage. Furthermore, the heating element 16 can have different heating temperature and response time by controlling the weight percentage of the carbon nanotubes for a given voltage. In one embodiment, the weight percentage of the carbon nanotubes in the heating element 16 can range from about 0.1% to about 5%. In other embodiments, the weight percentage of the carbon nanotubes in the heating element 16 can range from about 5% to about 10%. In other embodiments, the weight percentage of the carbon nanotubes in the heating element 16 can range from about 10% to about 30%. In other embodiments, the weight percentage of the carbon nanotubes in the heating element 16 can range from about 30% to about 90%.

The first electrode 12 and the second electrode 14 are electrically connected to the heating element 16. Furthermore, it is imperative that the first electrode 12 can be separated from the second electrode 14 to prevent short circuit of the two electrodes 12, 14.

When the matrix 162 is dispersed in the micropores of the carbon nanotube structure 164, parts of the carbon nanotube structure 164 can be exposed. The first electrode 12 and the second electrode 14 can be disposed on same surface or opposite surfaces of the heating element 16 to have contact with the carbon nanotube structure 164. The first electrode 12 and the second electrode 14 can be directly electrically attached to the heating element 16 by, for example, a conductive adhesive (not shown), such as silver adhesive. Because, some of the carbon nanotube structures have large specific surface area and are adhesive in nature, in some embodiments, the first electrode 12 and the second electrode 14 can be adhered directly to heating element 16. It should be noted that any other bonding ways may be adopted as long as the first electrode 12 and the second electrode 14 are electrically connected to the heating element 16. When the entire carbon nanotube structure 164 is enclosed within the matrix 162 as shown in FIG. 2, the first electrode 12 and the second electrode 14 can also be in the matrix 162 and make contact with the carbon nanotube structure 164. The first electrode 12 and the second electrode 14 can be electrically connected to two wires 19, which extend through outside of the matrix 162.

The shape of the first electrode 12 or the second electrode 14 is not limited and can be lamellar, rod, wire, and block among other shapes. In one embodiment shown in FIG. 1, the first electrode 12 and the second electrode 14 are both lamellar and parallel with each other. The material of the first electrode 12 and the second electrode 14 can be selected from metals, conductive resins, or any other suitable materials. In some embodiments, the carbon nanotubes in the heating element 16 are aligned along a direction from the first electrode 12 to the second electrode 14. In other embodiments, at least one of the first electrode 12 and the second electrode 14 includes at least a carbon nanotube film or at least a linear carbon nanotube structure. In one embodiment, each of the first electrode 12 and the second electrode 14 includes a linear carbon nanotube structure. The linear carbon nanotube structures are separately disposed on the two ends of the heating element 16.

The protecting layer 15 is disposed on a surface of the heating element 16. In one embodiment, the protecting layer 15 fully covers a top surface of the heating element 16. The protecting layer 15 and the heat-reflecting layer 17 are located at two opposite flanks of the heating element 16. The material of protecting layer 15 can be electrically conductive or insulative. The electrically conductive material can be metal or alloy. The insulative material can be resin, plastic or rubber. The thickness of the protecting layer 15 can range from about 0.5 μm to about 2 mm. When the material of the protecting layer 15 is insulative, the protecting layer 15 can electrically and/or thermally insulate the planar heater 10 from the external environment. The protecting layer 15 can also protect the heating element 16 including the carbon nanotube structure having an exposed portion from outside contaminants. The protecting layer 15 is an optional structure and can be omitted.

Referring to FIG. 16, in other embodiments, the planar heater 10 can have only a heating element 16, a first electrode 12 and a second electrode 14. The heating element 16 includes a matrix 162 and a carbon nanotube structure 164 enclosed therein. The first electrode 12 and the second electrode 14 are electrically connected to the carbon nanotube structure 164 and enclosed in the matrix 162. The matrix 162 contains the carbon nanotube structure 164, the first electrode 12 and the second electrode 14 therein. The carbon nanotube structure 164 extends from the first electrode 12 to the second electrode 14.

In use, when a voltage is applied to the first electrode 12 and the second electrode 14 of the planar heater 10, the carbon nanotube structure of the heating element 16 radiates heat at a certain wavelength. The object to be heated can be directly positioned on the planar heater 10 or kept away from the planar heater 10. By controlling the specific surface area of the carbon nanotube structure 164, selecting the voltage and the thickness of the carbon nanotube structure 164, the heating element 16 emits heat at different wavelengths. If the voltage is determined at a certain value, the wavelength of the electromagnetic waves emitted from the carbon nanotube structure 164 is inversely proportional to the thickness of the carbon nanotube structure 164. That is to say, the greater the thickness of carbon nanotube structure 164 is, the shorter the wavelength of the electromagnetic waves is. Further, if the thickness of the carbon nanotube structure 164 is determined at a certain value, the greater the voltage applied to the electrodes, the shorter the wavelength of the electromagnetic waves. As such, the planar heater 10 can easily be controlled for emitting a visible light and create general thermal radiation or emit infrared radiation.

Further, due to carbon nanotubes having an ideal black body structure, the carbon nanotube structure 164 has excellent electrical conductivity, thermal stability, and high thermal radiation efficiency. The planar heater 10 can be safely exposed, while working, to oxidizing gases in a typical environment. The planar heater 10 can radiate an electromagnetic wave with a long wavelength when a voltage is applied on the planar heater 10. The radiating efficiency is relatively high.

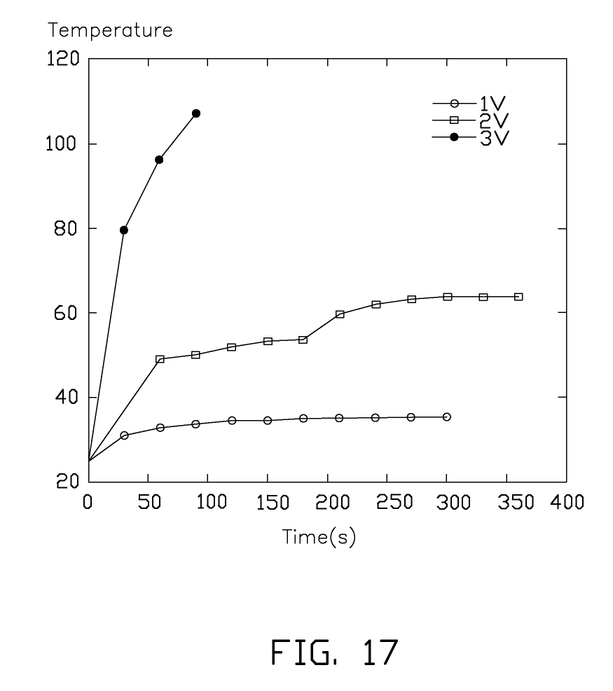

The voltage applied to the planar heater 10 depends on the material of the matrix 162 and the weight percentage of the carbon nanotubes so that the heating temperature of the planar heater 10 is below the melting point of the matrix 162. In one embodiment, the material of the matrix 162 is polymer and the weight percentage of the carbon nanotubes in the heating element 16 range from about 0.1% to about 5%, the voltage supplied to the planar heater 10 can range from about 0 volts to about 10 volts, and the heating temperature of the planar heater 10 is below 120° C. In other embodiments, the material of the matrix 162 is ceramic and the weight percentage of the carbon nanotubes in the heating element 16 range from about 0.1% to about 5%, the voltage supplied to the planar heater 10 can range from about 10 volts to about 30 volts and the heating temperature of the planar heater 10 can range from about 120° C. to about 500° C. In one embodiment, a planar heater 10 is tested. The planar heater 10 has a heating element 16 including an epoxy resin matrix and one hundred layers of drawn carbon nanotube films stacked on each other and dispersed therein. The heating element 16 is a square having a thickness of about 300 μm and a length of about 1 cm. The weight percentage of the carbon nanotubes in the heating element 16 is about 1%. Referring to FIG. 17, the higher the voltage supplied to the planar heater 10, the faster the temperature of the planar heater 10 rise. Thus, the planar heater 10 can be used in electric heaters, infrared therapy devices, electric radiators, and other related devices.

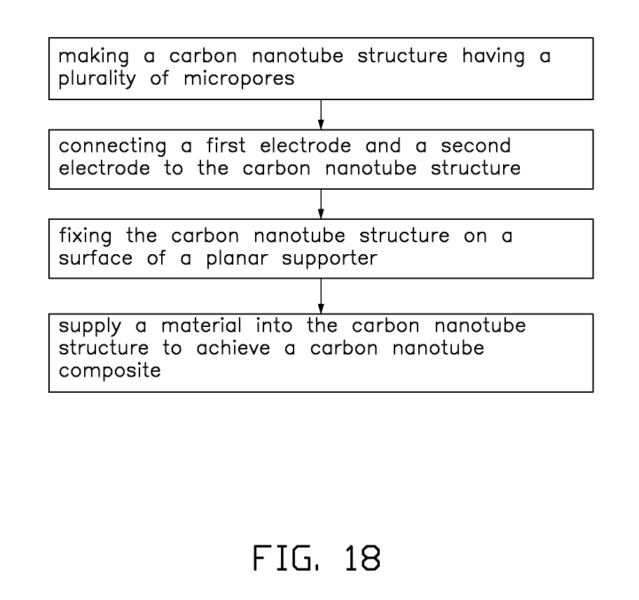

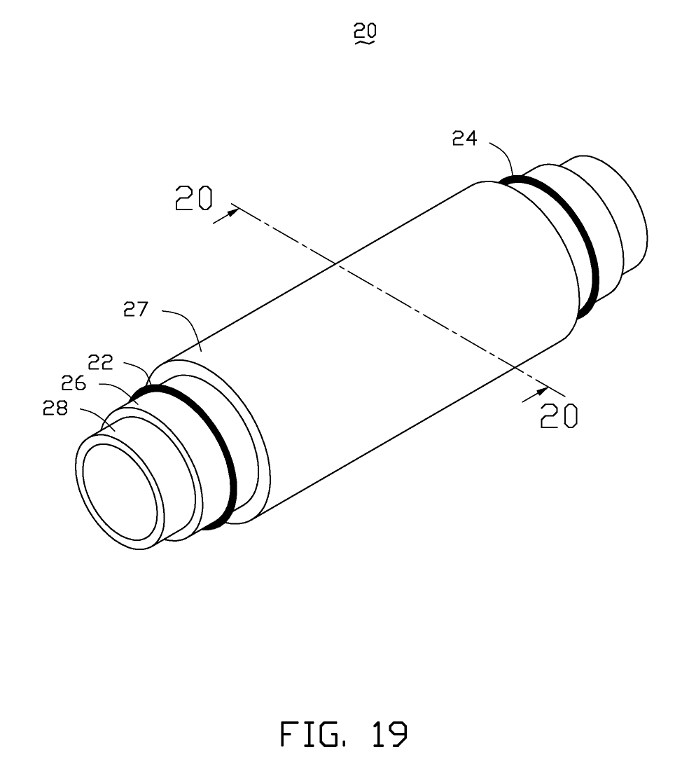

Referring FIG. 18, an embodiment of a method for making the planar heater 10 includes the steps of:

S1: making a carbon nanotube structure 164 having a plurality of micropores;

S2: connecting a first electrode 12 and a second electrode 14 to the carbon nanotube structure 164;

S3: fixing the carbon nanotube structure 164 on a surface of a planar supporter 18; and

S4: supply a material into the carbon nanotube structure 164 to achieve a carbon nanotube composite.

It is to be understood that, before step S4, an additional step of applying a heat-reflecting layer 17 to a surface of the planar supporter 18 can be performed. The heat-reflecting layer will then be located between the planar supporter 18 and the carbon nanotube structure 164. The heat-reflecting layer 17 can be created by coating method, chemical deposition method, ion sputtering method, and so on. In one embodiment, the heat-reflecting layer 17 is a film made of aluminum oxide. The heat-reflecting layer 17 can be coated on the carbon nanotube structure 164. After step S4, an additional step of applying a protecting layer 15 to cover the carbon nanotube structure 164 can be performed. The protecting layer 15 can be applied by a sputtering method or a coating method.

In step S1, the carbon nanotube structure 164 includes carbon nanotube films and linear carbon nanotube structures. The carbon nanotube films can be a drawn carbon nanotube film, a pressed carbon nanotube film, a flocculated carbon nanotube film, or a combination thereof.

In step S1, a method of making a drawn carbon nanotube film includes the steps of:

S11: providing an array of carbon nanotubes; and

S12: pulling out at least a drawn carbon nanotube film from the carbon nanotube array.

In step S11, a method of making the array of carbon nanotubes includes:

S111: providing a substantially flat and smooth substrate;

S112: applying a catalyst layer on the substrate;

S113: annealing the substrate with the catalyst at a temperature in the approximate range of 700° C. to 900° C. in air for about 30 to 90 minutes;

S114: heating the substrate with the catalyst at a temperature in the approximate range from 500° C. to 740° C. in a furnace with a protective gas therein; and

S115: supplying a carbon source gas to the furnace for about 5 to 30 minutes and growing a super-aligned array of the carbon nanotubes from the substrate.

In step S111, the substrate can be a P or N-type silicon wafer. Quite suitably, a 4-inch P-type silicon wafer is used as the substrate.

In step S112, the catalyst can be made of iron (Fe), cobalt (Co), nickel (Ni), or any combination alloy thereof.

In step S114, the protective gas can be made up of at least one of nitrogen (N₂), ammonia (NH₃), and a noble gas.

In step S115, the carbon source gas can be a hydrocarbon gas, such as ethylene (C₂H₄), methane (CH₄), acetylene (C₂H₂), ethane (C₂H₆), or any combination thereof.

In step S12, a drawn carbon nanotube film can be fabricated by the steps of:

S121: selecting one or more carbon nanotubes having a predetermined width from the array of carbon nanotubes; and

S122: pulling the carbon nanotubes to obtain nanotube segments at an even/uniform speed to achieve a uniform carbon nanotube film.

In step S121, the carbon nanotube segment includes a plurality of parallel carbon nanotubes. The carbon nanotube segments can be selected by using an adhesive tape as the tool to contact the super-aligned array of carbon nanotubes. In step S122, the pulling direction is substantially perpendicular to the growing direction of the super-aligned array of carbon nanotubes.

More specifically, during the pulling process, as the initial carbon nanotube segments are drawn out, other carbon nanotube segments are also drawn out end to end due to van der Waals attractive force between ends of adjacent segments. This process of pulling produces a substantially continuous and uniform carbon nanotube film having a predetermined width can be obtained.

After the step of S12, the drawn carbon nanotube film can be treated by applying organic solvent to the drawn carbon nanotube film to soak the entire surface of the carbon nanotube film. The organic solvent is volatile and can be selected from ethanol, methanol, acetone, dichloromethane, chloroform, or any appropriate mixture thereof. In the one embodiment, the organic solvent is ethanol. After being soaked by the organic solvent, adjacent carbon nanotubes in the carbon nanotube film that are able to do so, bundle together, due to the surface tension of the organic solvent when the organic solvent is volatilizing. In another aspect, due to the decrease of the specific surface area via bundling, the mechanical strength and toughness of the drawn carbon nanotube film are increased and the coefficient of friction of the carbon nanotube films is reduced. Macroscopically, the drawn carbon nanotube film will be an approximately uniform film.

The width of the drawn carbon nanotube film depends on a size of the carbon nanotube array. The length of the drawn carbon nanotube film can be set as desired. In one embodiment, when the substrate is a 4 inch type wafer, a width of the carbon nanotube film can be in an approximate range from 1 centimeter (cm) to 10 cm, the length of the carbon nanotube film can reach to about 120 m, the thickness of the drawn carbon nanotube film can be in an approximate range from 0.5 nm to 100 microns. Multiple films can be adhered together to obtain a film of any desired size.

In step S1, a method of making the pressed carbon nanotube film includes the following steps:

S11′: providing a carbon nanotube array and a pressing device; and

S12′: pressing the array of carbon nanotubes to obtain a pressed carbon nanotube film.

In step S11′, the carbon nanotube array can be made by the same method as S11.

In the step S12′, a certain pressure can be applied to the array of carbon nanotubes by the pressing device. In the process of pressing, the carbon nanotubes in the array of carbon nanotubes separate from the substrate and obtain the carbon nanotube film under pressure. The carbon nanotubes are substantially parallel to a surface of the carbon nanotube film.

In one embodiment, the pressing device can be a pressure head. The pressure head has a smooth surface. It is to be understood that, the shape of the pressure head and the pressing direction can determine the direction of the carbon nanotubes arranged therein. When a pressure head (e.g. a roller) is used to travel across and press the array of carbon nanotubes along a predetermined single direction, a carbon nanotube film having a plurality of carbon nanotubes primarily aligned along a same direction is obtained. It can be understood that there may be some variation in the film. Different alignments can be achieved by applying the roller in different directions over an array. Variations on the film can also occur when the pressure head is used to travel across and press the array of carbon nanotubes several of times, variation will occur in the orientation of the nanotubes. Variations in pressure can also achieve different angles between the carbon nanotubes and the surface of the semiconducting layer on the same film. When a planar pressure head is used to press the array of carbon nanotubes along the direction perpendicular to the substrate, a carbon nanotube film having a plurality of carbon nanotubes isotropically arranged can be obtained. When a roller-shaped pressure head is used to press the array of carbon nanotubes along a certain direction, a carbon nanotube film having a plurality of carbon nanotubes aligned along the certain direction is obtained. When a roller-shaped pressure head is used to press the array of carbon nanotubes along different directions, a carbon nanotube film having a plurality of sections having carbon nanotubes aligned along different directions is obtained.

In step S1, the flocculated carbon nanotube film can be made by the following method:

S11″: providing a carbon nanotube array;

S12″: separating the array of carbon nanotubes from the substrate to get a plurality of carbon nanotubes;

S13″: adding the plurality of carbon nanotubes to a solvent to get a carbon nanotube floccule structure in the solvent; and

S14″: separating the carbon nanotube floccule structure from the solvent, and shaping the separated carbon nanotube floccule structure into a carbon nanotube film to achieve a flocculated carbon nanotube film.

In step S11″, the carbon nanotube array can be fabricated by the same method as step (a1).

In step S12″, the array of carbon nanotubes is scraped off the substrate to obtain a plurality of carbon nanotubes. The length of the carbon nanotubes can be above 10 microns.

In step S13″, the solvent can be selected from water or volatile organic solvent. After adding the plurality of carbon nanotubes to the solvent, a process of flocculating the carbon nanotubes can, suitably, be executed to create the carbon nanotube floccule structure. The process of flocculating the carbon nanotubes can be selected from ultrasonic dispersion of the carbon nanotubes or agitating the carbon nanotubes. In one embodiment ultrasonic dispersion is used to flocculate the solvent containing the carbon nanotubes for about 10˜30 minutes. Due to the carbon nanotubes in the solvent having a large specific surface area and the tangled carbon nanotubes having a large van der Waals attractive force, the flocculated and tangled carbon nanotubes obtain a network structure (e.g., floccule structure).

In step S14″, the process of separating the floccule structure from the solvent includes the substeps of:

S14″1: filtering out the solvent to obtain the carbon nanotube floccule structure; and

S14″2: drying the carbon nanotube floccule structure to obtain the separated carbon nanotube floccule structure.

In step S14″1, the carbon nanotube floccule structure can be disposed in room temperature for a period of time to dry the organic solvent therein. The time of drying can be selected according to practical needs. The carbon nanotubes in the carbon nanotube floccule structure are tangled together.

In step S14″2, the process of shaping includes the substeps of:

S14″21: putting the separated carbon nanotube floccule structure into a container (not shown), and spreading the carbon nanotube floccule structure to obtain a predetermined structure;

S14″22: pressing the spread carbon nanotube floccule structure with a certain pressure to yield a desirable shape; and

S14″23: removing the residual solvent contained in the spread floccule structure to obtain the flocculated carbon nanotube film.

Through the flocculating, the carbon nanotubes are tangled together by van der Walls attractive force to obtain a network structure/floccule structure. Thus, the flocculated carbon nanotube film has good tensile strength. The flocculated carbon nanotube film includes a plurality of micropores defined by the disordered carbon nanotubes. A diameter of the micropores can be less than about 100 micron. As such, a specific area of the flocculated carbon nanotube film is extremely large. Additionally, the pressed carbon nanotube film is essentially free of a binder and includes a large amount of micropores. The method for making the flocculated carbon nanotube film is simple and can be used in mass production.

In step S1, a linear carbon nanotube structure includes carbon nanotube wires and/or linear carbon nanotube structures. The carbon nanotube wire can be made by the following steps:

S11′″: making a drawn carbon nanotube film; and

S12′″: treating the drawn carbon nanotube film to obtain a carbon nanotube wire.

In step S11′″, the method for making the drawn carbon nanotube film is the same the step S11.

In step S12′″, the drawn carbon nanotube film is treated with an organic solvent to obtain an untwisted carbon nanotube wire or is twisted by a mechanical force (e.g., a conventional spinning process) to obtain a twist carbon nanotube wire. The organic solvent is volatilizable and can be selected from ethanol, methanol, acetone, dichloroethane, or chloroform. After soaking in the organic solvent, the carbon nanotube segments in the carbon nanotube film can at least partially bundle into the untwisted carbon nanotube wire due to the surface tension of the organic solvent.

It is to be understood that a narrow carbon nanotube film can serve as a wire. In this situation, through microscopically view, the carbon nanotube structure 164 is a flat film, and through macroscopically view, the narrow carbon nanotube film would look like a long wire.

In step S1, the linear carbon nanotube structure can be made by bundling two or more carbon nanotube wires together. The linear carbon nanotube structure can be twisted or untwisted. In the untwisted linear carbon nanotube structure, the carbon nanotube wires are parallel with each other, and the carbon nanotubes can be kept together by an adhesive (not shown). In the twisted linear carbon nanotube structure, the carbon nanotube wires twisted with each other, and can be adhered together by an adhesive or a mechanical force.

In step S1, the drawn carbon nanotube film, the pressed carbon nanotube film, the flocculated carbon nanotube film, or the linear carbon nanotube structure can be overlapped, stacked with each other, and/or disposed side by side to make a carbon nanotube structure 164. It is also understood that this carbon nanotube structure 164 can be employed by all embodiments.

In step S2, the first electrode 12 and the second electrode 14 are made of conductive materials, and applied on the surface of the carbon nanotube structure 164 by sputtering method or coating method. The first electrode 12 and the second electrode 14 can also be attached on the carbon nanotube structure 164 directly with a conductive adhesive or by a mechanical force. Further, silver paste can be applied on the surface of the carbon nanotube structure 164 directly to obtain the first electrode 12 and the second electrode 14.

In step S3, the carbon nanotube structure 164 can be fixed on the surface of the planar supporter 18 by an adhesive. The carbon nanotube structure 164 can be fixed on the surface of the planar supporter by a mechanical method, such as bolt, splint.

In the step S4, the material can be a polymer material or an inorganic nonmetal material. The polymer material or the nonmetal material can be applied in a liquid state, in a gaseous state or in a slurry state. The liquid state or slurry state material is hardenable. The polymer material can be thermoplastic polymer or thermosetting polymer. The thermosetting material can be selected from epoxy resin, bismaleimide resin, cyanate ester resin, or silicone rubber. The thermoplastic material can be selected from polypropylene, polyethylene, polyvinyl alcohol, or polymethacrylate resin. The inorganic nonmetal material can be selected from glass, ceramic or semiconductor. The inorganic nonmetal material can be in a slurry state or in a gaseous state. The slurry state inorganic nonmetal material can be obtained by the following steps: supplying a plurality of inorganic nonmetal material particles; adding these inorganic nonmetal material particles into a solvent; mixing round the solvent with the material to form a slurry state inorganic nonmetal material. The gaseous state inorganic nonmetal material can be obtained by a method such as sputtering, chemical vapor deposition (CVD), physical deposition (CVD) or thermal evaporation.

When the material is applied in the liquid state, the carbon nanotube structure 164 can be immersed in the liquid state material. When the material is applied in the gaseous state, the gaseous state material can be deposited on the carbon nanotube structure 164. When the material is applied in the slurry state, the slurry can be applied to the carbon nanotube structure 164 by coating or screen printing.

In step S4, according to one embodiment, the step of applying the material into the carbon nanotube structure 164 includes: S41: providing a die, disposing the carbon nanotube structure 164 in the die; S42: providing a liquid-state thermosetting polymer; S43: injecting the liquid-state thermosetting polymer into the die, and thereby immersing the carbon nanotube film structure in the liquid-state thermosetting polymer to obtain a carbon nanotube composite preform; and S44: solidifying the liquid-state thermosetting polymer to achieve a carbon nanotube composite.

In step S42, according to one embodiment, a viscosity of the liquid-state thermosetting polymer is less than 5 pascal-seconds (Pa·s), which can be kept at room temperature for at least 30 minutes. The liquid-state thermosetting polymer includes polymer and at least one additive. The at least one additive can be selected from solidifying agent, modifying agent, diluting agent, filler, or any combination thereof. A mass ratio of the polymer to the additive can range from about 7:3 to about 19:1. The liquid-state thermosetting polymer can be selected from phenolic resin, epoxy resin, bismaleimide resin, triazine resin, polyimide, or polymethyl methacrylate. The solidifying agents can be selected from aliphatic amine, aliphatic cyclic amine, aromatic amine, polyamide, acid anhydride, tertiary amine, or any combination thereof, and are ultimately used to accelerate the process of solidifying the liquid-state thermosetting polymer. The modifying agents can be selected from polysulphide rubber, polyamide resin, acrylonitrile rubber, or any combination thereof, and are ultimately used to improve the property of the liquid-state thermosetting polymer. The diluting agents can be selected from diglycidyl ether, polyglycidyl ether, butyl epoxy propyl ether 660, allylphenol, or any combination thereof. The fillers can be selected from asbestos fiber, glass fiber, quartz powder, aluminum oxide, or any combination thereof, and are ultimately used to improve the heat-dissipation of the liquid-state thermosetting polymer.

In the step of S42, according to one embodiment, the liquid-state thermosetting polymer can be fabricated by the following substeps: (S421) providing a polymer in a container, and heating and agitating the polymer at a temperature of less than 300° C.; (S422) adding at least one additive into the polymer; and (S423) heating and uniformly agitating the polymer with the at least one additive at a temperature of less than 300° C., thereby obtaining the liquid-state thermosetting polymer.

In step S42, according to other embodiments, the method of fabricating the liquid-state thermosetting polymer includes: (S421′) providing a mixture of epoxy resin of glycidyl ether and epoxy resin of glycidyl fat disposed in a container, heating the mixture to a temperature ranging from about 30° C. to about 60° C., and agitating the mixture for about 10 minutes; (S422′) adding aliphatic amine and diglycidyl ether to the mixture; and (S423′) heating the mixture to a temperature ranging from about 30° C. to about 60° C., and obtaining a liquid-state thermosetting polymer comprising epoxy resin.

In the step S43, the lower the viscosity of the liquid-state thermosetting polymer, the easier liquid-state thermosetting polymer can permeate into the microporous structure of the carbon nanotube structure 164. In order to make the liquid-state thermosetting polymer better permeate into the carbon nanotube structure 164 well, the air in the die can be removed and create a vacuum therein. The pressure in the die can be kept more than 10 minutes.

In step S44, the liquid-state thermosetting polymer can be solidified by the following substeps: S441 heating the carbon nanotube composite preform to a predetermined temperature and maintaining the predetermined temperature for no more than 100 hours; and S442 cooling the carbon nanotube composite preform to room temperature, thereby obtaining the carbon nanotube composite.

According to one embodiment, the step S441 includes the following substeps: S4411 heating the carbon nanotube composite preform to a temperature ranging from 50° C. to 70° C. for a period of about 1-3 hours; S4412 heating the carbon nanotube composite preform to a temperature ranging from 80° C. to 100° C. for a period of about 1 hour to 3 hours; S4413 heating the carbon nanotube composite preform to a temperature ranging from about 110° C. to about 150° C. for a period of about 2-20 hours, whereby the liquid-state thermosetting polymer becomes solidified; and S4414 cooling the carbon nanotube composite preform to room temperature, and removing the carbon nanotube composite preform from the die to obtain the carbon nanotube composite.

It can be understood that in the step S44, the carbon nanotube composite preform can be heated directly into the temperature ranging from about 110° C. to about 150° C. Examples of method of making the carbon nanotube composite are taught by US PGPub. 20090155467A1 to Wang et al. The methods and carbon nanotube composites taught therein are hereby incorporated by reference.

As described above, the planar heater 10 can be a flat stacked-type heater, which uses a carbon nanotube composite structure as a heating element 16 whose performance is further improved by the presence of the matrix. Selectively, the heat-reflecting layer 17, the supporter 18, the protecting layer 15 can be applied according to practical needs.

### Hollow Heater/Three-Dimensional Heater

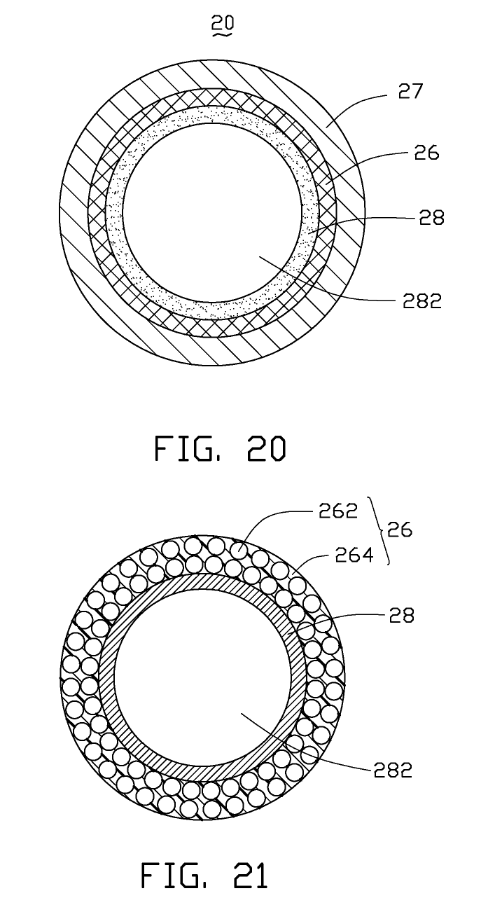

Referring to FIGS. 19 and 20, a hollow heater 20 is shown. The hollow heater 20 includes a hollow supporter 28, a heating element 26, a first electrode 22, a second electrode 24, and a heat-reflecting layer 27. The heating element 26 is disposed on an outer circumferential surface of the hollow supporter 28. The heat-reflecting layer 27 is disposed on an outer circumferential surface of the heating element 26. The hollow supporter 28 and the heat-reflecting layer 27 are located at two opposite circumferential surfaces of the heating element 26. The first electrode 22 and the second electrode 24 are electrically connected to the heating element 26 and spaced from each other. In one embodiment, the first electrode 22 and the second electrode 24 are located on opposite ends of the heat-reflecting layer 27.

The hollow supporter 28 is configured to support the heating element 26 and the heat-reflecting layer 27. The hollow supporter 28 defines a hollow space 282. The shape and size of the hollow supporter 28 can be determined according to practical demands. For example, the hollow supporter 28 can be shaped as a hollow cylinder, a hollow ball, or a hollow cube. Other characters of the hollow supporter 28 are the same as the planar supporter 18 disclosed herein. In one embodiment, the hollow supporter 28 is a hollow cylinder.

The heating element 26 can be attached on the inner surface or wrapped on the outer surface of the hollow supporter 28. In the embodiment shown in FIGS. 20 and 21, the heating element 26 is disposed on the outer circumferential surface of the hollow supporter 28. The heating element 26 can be fixed on the hollow supporter 28 with an adhesive (not shown) or by a mechanical force. Similar to the heating element 16 discussed above, the heating element 26 also includes a carbon nanotube composite structure. The carbon nanotube composite structure can include a matrix and one or more carbon nanotube structures. The characters of the carbon nanotube structure are the same as the carbon nanotube structure disclosed in the above. All embodiments of the carbon nanotube structure discussed above can be incorporated into the hollow heater 20. Same as disclosed herein, the carbon nanotube structure can be a carbon nanotube film structure, a linear carbon nanotube structure or a combination thereof.

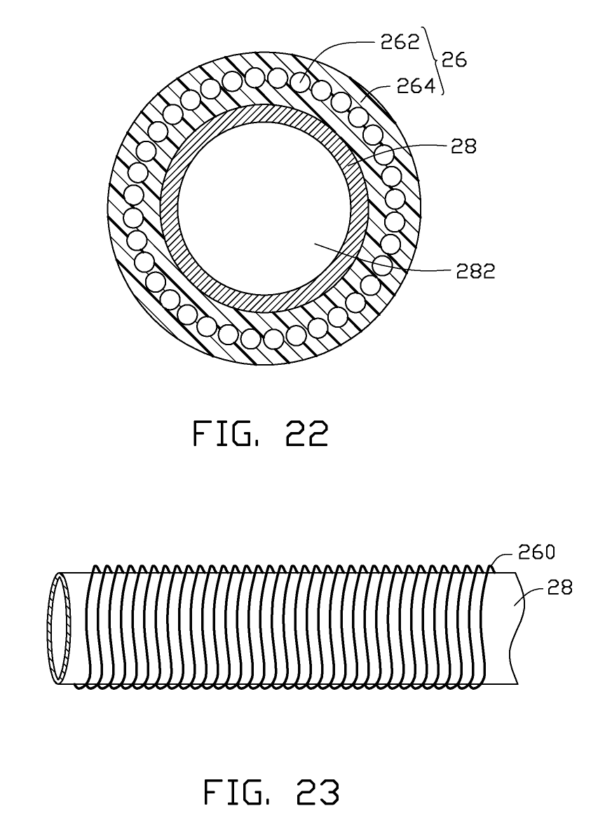

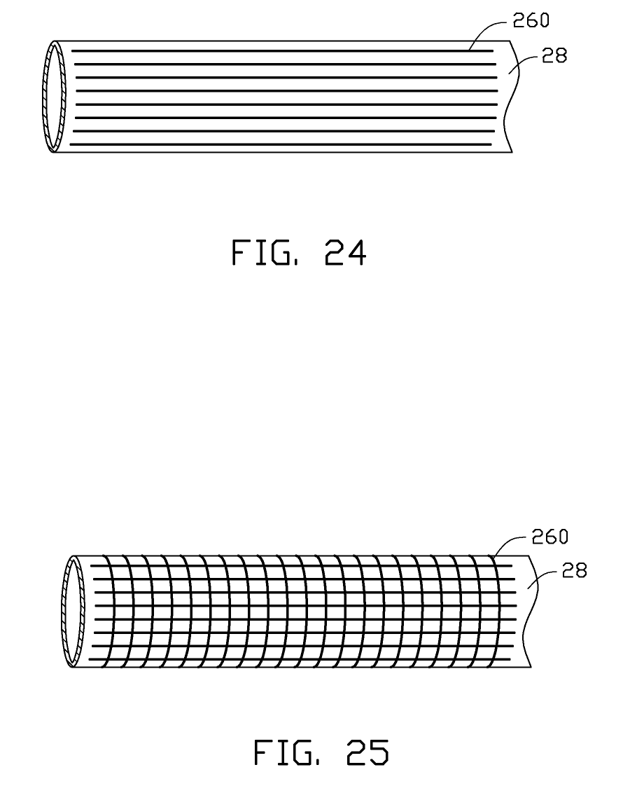

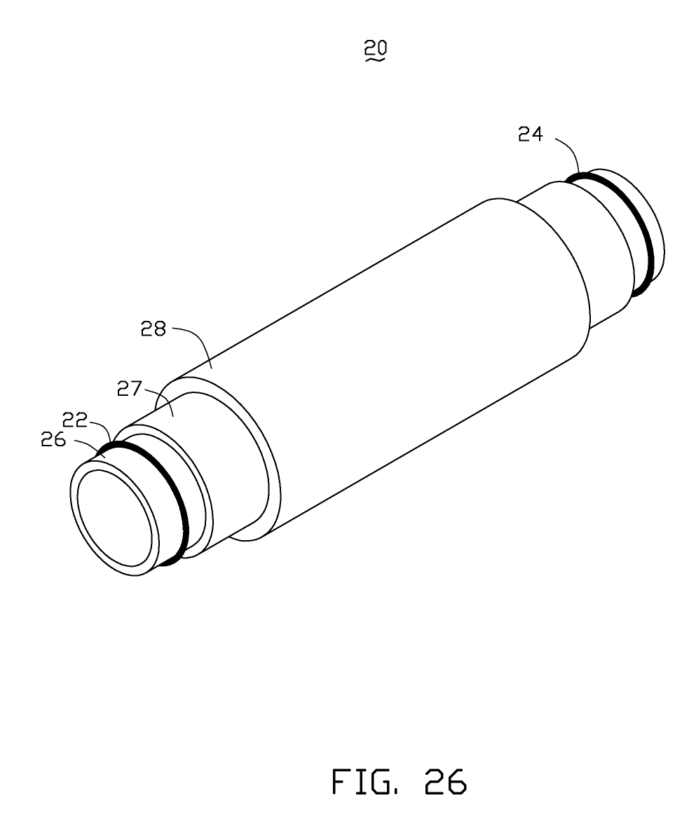

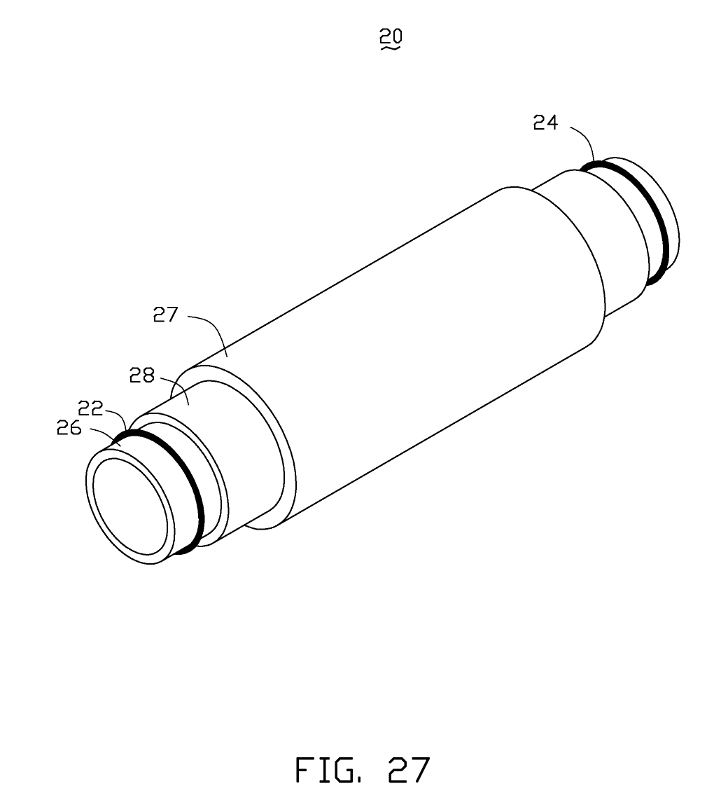

The heating element 26 can be a layer-shaped carbon nanotube composite structure, a linear carbon nanotube composite structure or combinations thereof. Referring to FIG. 21, the heating element 26 can include a carbon nanotube film structure 262 wrapped on a surface of the hollow supporter 28 and a matrix 264 dispersed in the micropores of the carbon nanotube film structure 262. Referring to FIG. 22, the heating element 26 can include a matrix 264 wrapped on a surface of the hollow supporter 28 and a carbon nanotube film structure 262 entirely enclosed in the matrix 264. Referring to FIG. 23, when the heating element 26 includes a single linear carbon nanotube composite structure 260, the single linear carbon nanotube composite structure 260 can spirally twist about the hollow supporter 28. In another example, referring to FIG. 24, when the heating element 26 includes two or more linear carbon nanotube composite structures 260, the linear carbon nanotube composite structures 260 can be disposed on the surface of the hollow supporter 28 and parallel with each other. The linear carbon nanotube composite structures 260 can be disposed side by side or separately. In another example shown in FIG. 25, when the heating element 26 includes a plurality of linear carbon nanotube composite structures 260, the linear carbon nanotube composite structures 260 can be knitted to obtain a net disposed on the surface of the hollow supporter 28. It is understood that these linear carbon nanotube composite structures 260 can be applied to the inside of the supporter 28.

The first electrode 22 and the second electrode 24 can be disposed on a same surface or opposite surfaces of the heating element 26. Furthermore, it is imperative that the first electrode 22 can be separated from the second electrode 24 to prevent short circuit of the two electrodes 22, 24. The first electrode 22 and the second electrode 24 can be the same as the first electrode 12 and the second electrode 14 discussed above. All embodiments of the electrodes discussed herein can be incorporated into the hollow heater 20. In the embodiment, the first electrode 22 and the second electrode 24 are both wire ring surrounded the heating element 26 and parallel with each other. And each of the first electrode 22 and the second electrode 24 includes a linear carbon nanotube structure. The linear carbon nanotube structures disposed on the two ends of the heating element 26, and wrap the heating element 26 to obtain two wire rings.

The heat-reflecting layer 27 can be located on the inner surface of the hollow supporter 28, and the heating element 26 is disposed on the inner surface of the heat-reflecting layer 27 as shown in FIG. 26. The heat-reflecting layer 27 can be located on the outer surface of the hollow supporter 28, and the heating element 26 is disposed on the inner surface of the hollow supporter 28 as shown in FIG. 27. Alternatively, the heat-reflecting layer 27 can be omitted. Without the heat-reflecting layer 27, the heating element 26 can be located directly on the hollow supporter 28. The other properties of the heat-reflecting layer 27 are the same as the heat-reflecting layer 17 discussed above.

When one of the inner circumferential and the outer circumferential surfaces of the heating element 26 is exposed to air, the hollow heater 20 can further include a protecting layer (not shown) attached to the exposed surface of the heating element 26. The protecting layer can protect the hollow heater 20 from the environment. The protecting layer can also protect the heating element 26 from impurities. In one embodiment, the heating element 26 is disposed between the hollow supporter 28 and the heat-reflecting layer 27 as shown in FIG. 19, therefore a protecting layer would not necessarily be needed.

In use of the hollow heater 20, an object that will be heated can be disposed in the hollow space 282 (shown in FIG. 20). When a voltage is applied to the first electrode 22 and the second electrode 24, the carbon nanotube structure of the heating element 26 of the hollow heater 20 generates heat. As the object is disposed in the hollow space 282, the whole body of the object can be heated evenly.

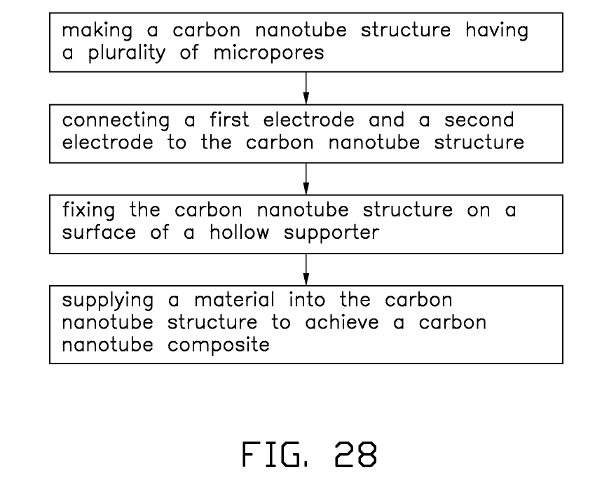

Referring to FIG. 28, an embodiment of a method for making the hollow heater 20 includes the steps of:

M1: making a carbon nanotube structure having a plurality of micropores;

M2: connecting a first electrode 22 and a second electrode 24 to the carbon nanotube structure;

M3: fixing the carbon nanotube structure on a surface of a hollow supporter 28; and

M4: supplying a material into the carbon nanotube structure to achieve a carbon nanotube composite.

It is to be understood that, after step M4, an additional step of applying a protecting layer to cover the carbon nanotube composite can be carried out. The protecting layer can be obtained by a sputtering method or a coating method.

In step M1, the detailed process of making the carbon nanotube structure is the same as the step S1 disclosed herein.

The detailed process of M2 can be the same as the step S2 discussed above.

In step M3, the carbon nanotube structure can be fixed on an inner or an outer surface of the hollow supporter 28 with an adhesive or by mechanical method. The carbon nanotube structure can wrap the outer surface of the hollow supporter 28. It is to be understood that, in one embodiment, before fixing the carbon nanotube structure on the surface of the hollow supporter, an additional step of applying a heat-reflecting layer 27 attached to a surface of the hollow supporter 28 can be performed. The heat-reflecting layer can be obtained on the outer surface or the inner surface of the hollow supporter 28. And the carbon nanotube structure is disposed on the surface of heat-reflecting layer 27, e.g. the heat-reflecting layer is located between the hollow supporter 28 and the carbon nanotube structure. The heat-reflecting layer 27 can be applied by coating method, chemical deposition method, ion sputtering method, and so on. In one embodiment, the heat-reflecting layer 27 is a film made of aluminum oxide.

The detail process of the step M4 can be the same as the step S4 discussed above.

According to other embodiments, the method for making the hollow heater 20 includes the steps of:

M1′: making a carbon nanotube structure having a plurality of micropores;

M2′: connecting a first electrode 22 and a second electrode 24 to the carbon nanotube structure;

M3′: applying a material into the carbon nanotube structure to achieve a flexible carbon nanotube composite; and

M4′: fixing the flexible carbon nanotube composite on a surface of the hollow supporter 28.

In step M4′, because the carbon nanotube composite is a flexible carbon nanotube composite, the flexible carbon nanotube composite can be curved and fixed on a surface of the hollow supporter 28.

It is to be understood that, in step M4′, before fixing the flexible carbon composite on a surface of the hollow supporter 28, an additional steps of applying a reflecting layer 27 on the linear supporter 28 can be performed. After step M4′, an additional step of applying a protecting layer on the flexible carbon composite, the first electrode 22 and the second electrode 24 can be performed.

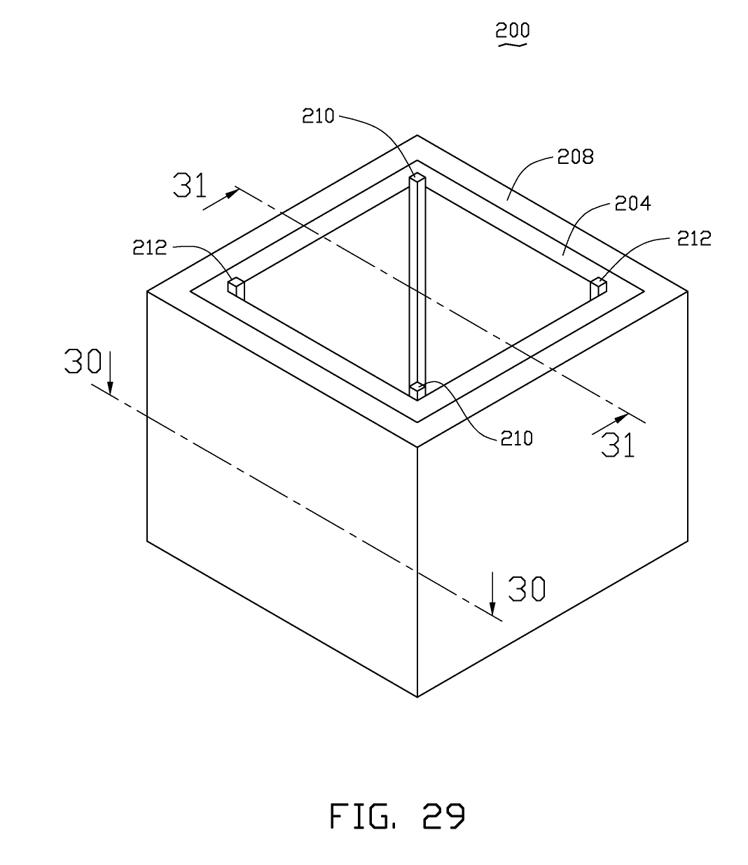

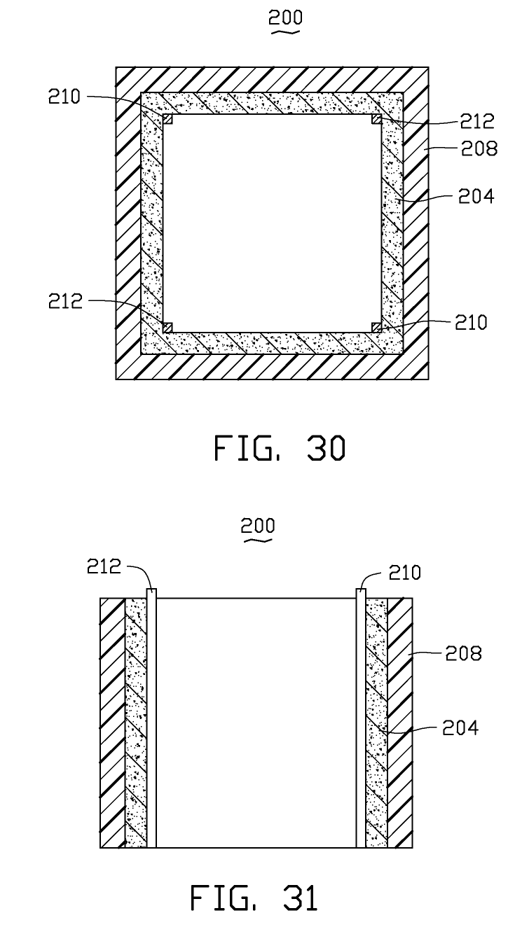

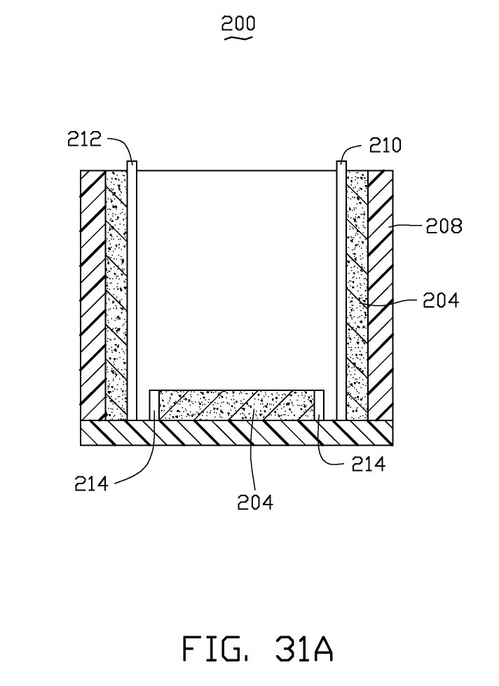

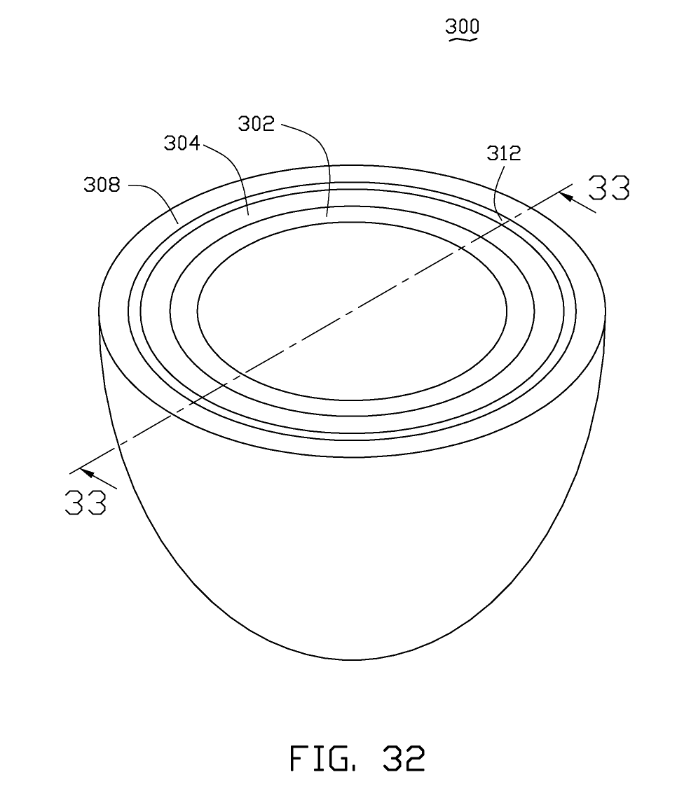

Referring to FIGS. 29, 30 and 31, a hollow heater 200 is provided according to other embodiments. The hollow heater 200 includes a heating element 204, a first electrode 210, a second electrode 212, and a heat-reflecting layer 208. The heating element 204 has a hollow cube configuration. The first electrode 210 and the second electrode 212 are electrically connected to the heating element 204 and spaced from each other. The first electrode 210 and the second electrode 212 are wire shaped and extend from a bottom end of the heating element 204 to a position higher above a top end of the heating element 204 for connecting outer power supply when the hollow heater 200 is positioned in the position shown in FIG. 31. The heat-reflecting layer 208 is disposed on an outer circumferential surface of the hollow cube heating element 204. The hollow heater 200 can include more than one first electrode 210 and second electrode 212.

In detail, the hollow heater 200 has a rectangular cross-section. The heating element 204 is attached on an inner surface of the heat-reflecting layer 208 and also has a rectangular cross-section. A pair of first electrodes 210 is disposed at first diagonal corners of the rectangular cross-section of the heating element 204 and a pair of second electrodes 212 is disposed at second diagonal corners of the rectangular cross-section of the heating element 204. Thus, the first electrodes 210 and the second electrodes 212 are alternately arranged at the corners of the rectangular cross-section of the heating element 204 in the hollow heater 200. Each part of the heating element 204 between adjacent first electrode 210 and second electrode 212 is controlled to produce heat according to practical need by selectively supplying voltage to corresponding first electrode 210 and second electrode 212. Additionally, the hollow heater 200 can have two openings provided at opposite ends. Alternatively, the hollow heater 200 may be designed to have only one opening as shown in FIG. 31A. As shown in FIG. 31A, the hollow heater 200 has a bottom surface (not labeled). An object needed to be heated can be put into the hollow heater 200 through the top opening and supported by the bottom surface. Furthermore, a heating element 204 which is electrically connected with two electrodes 214 can be located on the bottom surface.

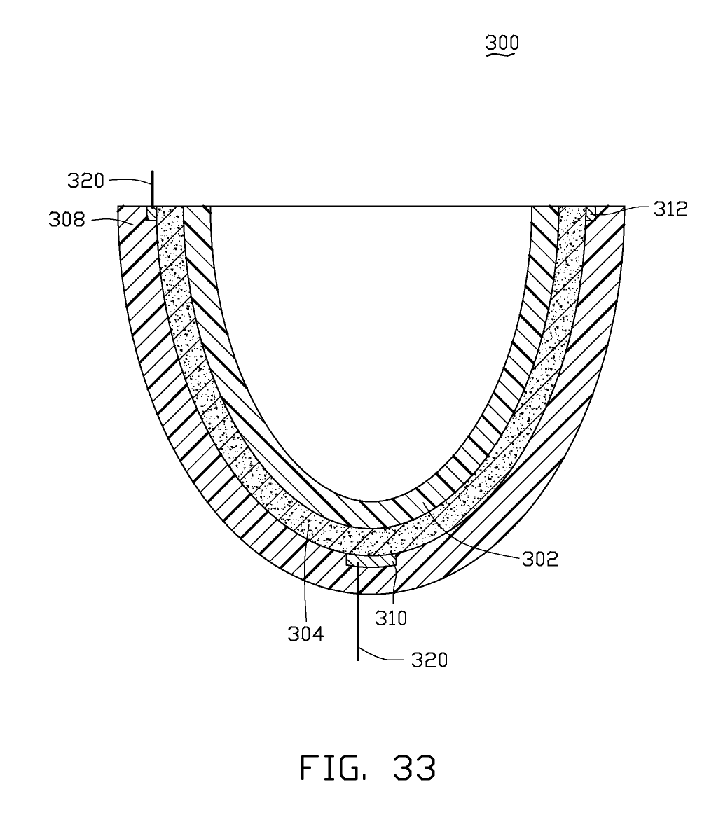

Referring to FIGS. 32 and 33, a hollow heater 300 is provided according to other embodiments. The hollow heater 300 includes a hollow supporter 302, a heating element 304, a first electrode 310, a second electrode 312, and a heat-reflecting layer 308. The hollow heater 300 can be a hollow hemisphere, hollow parabola or other shapes. The heating element 304 is disposed on an outer circumferential surface of the hollow supporter 302. The heat-reflecting layer 308 is disposed on an outer circumferential surface of the heating element 304. In one embodiment, the hollow heater 300 is a hollow hemisphere, the first electrode 310 is round and disposed on bottom of the hemispherical hollow supporter 302. The second electrode 312 is ring-shape and located on top of the hemispherical hollow supporter 302. The first electrode 310 and the second electrode 312 can be electrically connected to two conductive wires 320, which extend through outside of the heat-reflecting layer 308. In detail, the first electrode 310 is positioned at the lowest point of the heating element 304 and is covered by the heat-reflecting layer 308. The second electrode 312 encircles a top part of the heating element 304. An inner surface of the hollow supporter 302 can be designed according to an outer surface of the object needed to be heated, so that the inner surface of the hollow supporter 302 can match the outer surface of the object needed to be heated. This helps to reduce the thermal resistance between the inner surface of the hollow supporter 302 and the outer surface of the object needed to be heated.

### Linear Heater

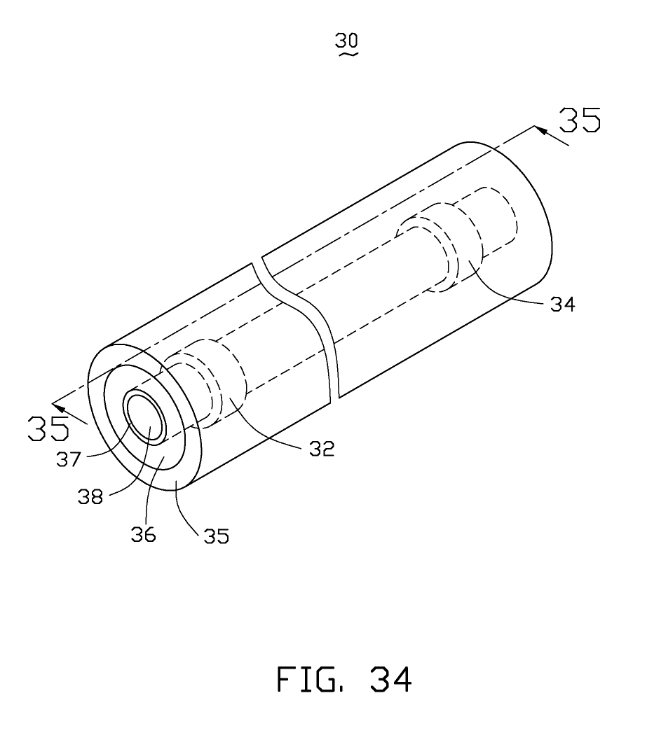

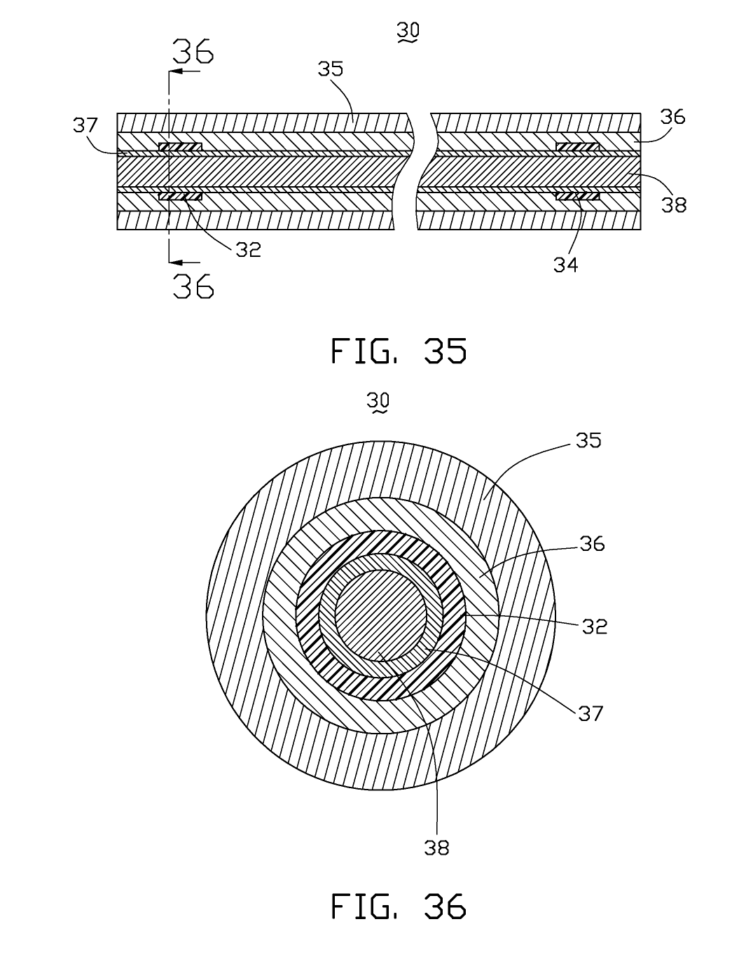

Referring to FIGS. 34, 35 and 36, a linear heater 30 is provided. The linear heater 30 includes a linear supporter 38, a reflecting layer 37, a heating element 36, a first electrode 32, a second electrode 34, and a protecting layer 35. The reflecting layer 37 is on the outer surface of the linear supporter 38; the heating element 36 wraps the surface of the reflecting layer 37. The first electrode 32 and the second electrode 34 are separately connected to the heating element 36. In one embodiment, the first electrode 32 and the second electrode 34 are located on the heating element 36. The protecting layer 35 covers the heating element 36, the first electrode 32 and the second electrode 34. A diameter of the linear heater 30 is very small compared with a length of itself. In one embodiment, the diameter of the linear heater 30 is in a range from about 1 μm to about 1 cm. A ratio of length to diameter of the linear heater 30 can be in a range from about 50 to about 5000.

The linear supporter 38 is configured for supporting the heating element 36 and the heat-reflecting layer 37. The linear supporter 38 has a linear structure, and the diameter of the linear supporter 38 is small compared with a length of the linear supporter 38. Other characters of the linear supporter 38 can be the same as the planar supporter 18 as disclosed herein.

The heating element 36 can be attached on the surface of the linear supporter 38 directly. When the heat-reflecting layer 37 wraps on the surface of the linear supporter 38, the heating element 36 can be attached on the surface of the heat-reflecting layer 37. The same as the heating element 16 discussed above, the heating element 36 includes a carbon nanotube composite structure. The carbon nanotube composite structure can include a matrix and one or more carbon nanotube structure. The characteristics of the carbon nanotube structure can be the same as the carbon nanotube structure discussed above. The heating element 36 can be located on surface of the linear supporter 38 like the heating element 26 on the surface of the hollow supporter 28 discussed above.

The first electrode 32 and the second electrode 34 can be disposed on a same surface or opposite surfaces of the heating element 36. The shape of the first electrode 32 or the second electrode 34 is not limited and can be lamellar, rod, wire, and block among other shapes. In the embodiment shown in FIGS. 33 and 34, the first electrode 32 and the second electrode 34 are both lamellar rings. In some embodiments, the carbon nanotubes in the heating element 36 are aligned along a direction perpendicular to the first electrode 32 and the second electrode 34. In other embodiments, at least one of the first electrode 32 and the second electrode 34 includes at least one carbon nanotube film or at least a linear carbon nanotube structure. In other embodiments, each of the first electrode 32 and the second electrode 34 includes a linear carbon nanotube structure. The linear carbon nanotube structures disposed on the two ends of the heating element 36, and wrap the heating element 36 to obtain two rings.

The protecting layer 35 is disposed on the outer surface of the heating element 36. In one embodiment, the protecting layer 35 fully covers the outer surface of the heating element 36. The heating element 36 is located between the protecting layer 35 and the heat-reflecting layer 37.

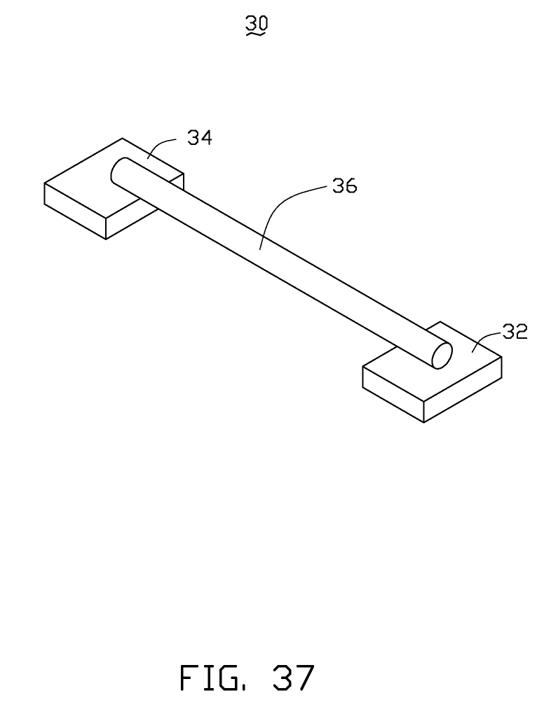

Referring to FIG. 37, in other embodiments, the linear heater 30 can include only a heating element 36, a first electrode 32, and a second electrode 34. The first electrode 32 and the second electrode 34 are separately connected to the heating element 36. The heating element 36 is a linear carbon nanotube composite structure.

In use of the linear heater 30, the heater 30 can be spirally twisted about a target, and the target will be heated from outside. The heater 30 can also be inserted into the target to heat the target inside. Given the small size of the linear heater 30, it can be used in applications with limited space or in the field of MEMS for example.

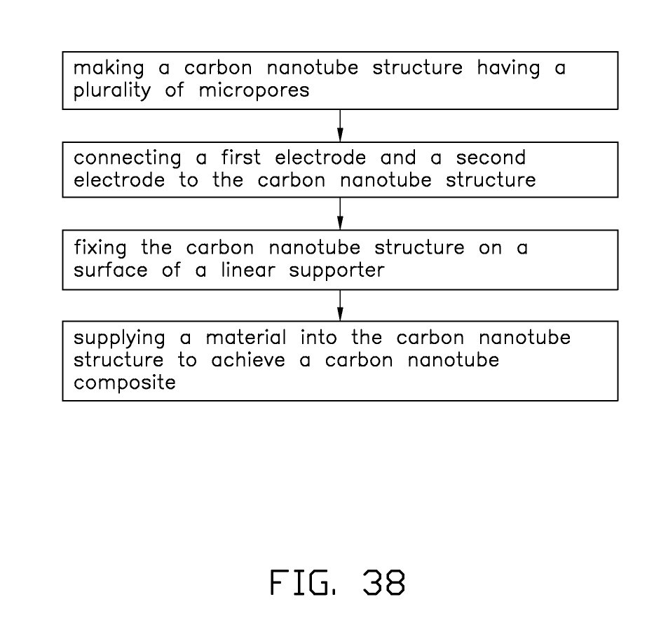

Referring to FIG. 38, an embodiment of a method for making the linear heater 30 includes the steps of:

N1: making a carbon nanotube structure having a plurality of micropores;

N2: connecting a first electrode 32 and a second electrode 34 to the carbon nanotube structure;

N3: fixing the carbon nanotube structure on a surface of a linear supporter 38; and

N4: supplying a material into the carbon nanotube structure to achieve a carbon nanotube composite.

It is to be understood that, after N4, an additional step of applying a protecting layer 35 on the carbon nanotube composite can be provided.

In step N1, the detailed process of making the carbon nanotube structure is the same as the step S1 disclosed herein.

The detailed process of N2 can be the same as the step S2 discussed above.

In step N3, the carbon nanotube structure can be wrapped on the surface of linear supporter 38 with an adhesive or by mechanical method. When the carbon nanotube structure includes a plurality of carbon nanotubes substantially oriented along a same direction, the oriented direction can be from one end of the supporter 38 to another end of the supporter 38. The first electrode and the second electrode are disposed on the two ends of the linear supporter. It is to be understood that, in one embodiment, before fixing the carbon nanotube structure on the surface of the linear supporter 38, an additional step of applying a heat-reflecting layer 37 attached to a surface of the linear supporter 38 can be performed. The heat-reflecting layer 37 can be applied on the outer surface or the inner surface of the linear supporter 38. And the carbon nanotube structure is disposed on the surface of heat-reflecting layer 37, e.g. the heat-reflecting layer is located between the linear supporter 38 and the carbon nanotube structure. The heat-reflecting layer 37 can be applied by coating method, chemical deposition method, ion sputtering method, and so on. In one embodiment, the heat-reflecting layer 37 is a film made of aluminum oxide.

The detail process of the step N4 can be the same as the step S4 discussed above.

According to other embodiments, the method for making the linear heater 30 includes the steps of:

N1′: making a carbon nanotube structure having a plurality of micropores;

N2′: connecting a first electrode 32 and a second electrode 34 to the carbon nanotube structure;

N3′: applying a material into the carbon nanotube structure to achieve a carbon nanotube composite; and

N4′: fixing the flexible carbon nanotube composite on a surface of the linear supporter 38.

In step N4′, because the carbon nanotube composite is a flexible carbon nanotube composite, the flexible carbon nanotube composite can be curved and fixed on a surface of the linear supporter 38.

It is to be understood that, in step N4′, before fixing the flexible carbon composite on a surface of the linear supporter, an additional steps of applying a reflecting layer 37 on the linear supporter 38 can be performed. After step N4′, an additional step of applying a protecting layer 35 on the heating element 36, the first electrode 32 and the second electrode 34 can be performed.

The detail process of the step N3′ can be the same as the step S4 discussed above.

It is to be understood that the above-described embodiments are intended to illustrate rather than limit the invention. Variations may be made to the embodiments without departing from the spirit of the invention as claimed. It is understood that any element of any one embodiment is considered to be disclosed to be incorporated with any other embodiment. The above-described embodiments illustrate the scope of the invention but do not restrict the scope of the invention.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

What claimed is:

1. A method of making a planar heater, the method comprising steps of:
(a) providing a carbon nanotube structure having a plurality of micropores;
(b) connecting a first electrode and a second electrode to the carbon nanotube structure;
(c) fixing the carbon nanotube structure on a surface of a planar supporter; and
(d) supplying a material into the carbon nanotube structure to achieve a carbon nanotube composite structure.

2. The method of claim 1, further comprising a step of (e) applying a heat-reflecting layer to the surface of the planar supporter, wherein step (e) is performed before step (c).

3. The method of claim 1, further comprising an additional step of applying a protecting layer to cover the carbon nanotube composite structure after step (d).

4. The method of claim 1, wherein in step (a), the carbon nanotube structure comprises a carbon nanotube film or a linear carbon nanotube structure.

5. The method of claim 4, wherein the carbon nanotube film includes a drawn carbon nanotube film, a pressed carbon nanotube film or a flocculated carbon nanotube film.

6. The method of claim 1, wherein in step (b), the first electrode and the second electrode comprises conductive materials and are applied on a surface of the carbon nanotube structure by a sputtering method or a coating method.

7. The method of claim 1, wherein in step (b), the first electrode and the second electrode are directly attached on the carbon nanotube structure with a conductive adhesive or by a mechanical force.

8. The method of claim 1, wherein in step (b), silver paste is applied on a surface of the carbon nanotube structure directly to obtain the first electrode and the second electrode.

9. The method of claim 1, wherein in step (c), the carbon nanotube structure is fixed on the surface of the planar supporter by an adhesive or by a mechanical method.

10. The method of claim 1, wherein in step (d), the material is in a liquid state and the carbon nanotube structure is immersed in the material.

11. The method of claim 1, wherein in step (d), the material is in a gaseous state and the material is deposited on the carbon nanotube structure.

12. The method of claim 1, wherein in step (d), the material is in a slurry state and is applied to the carbon nanotube structure by coating or screen printing.

13. The method of claim 1, wherein in step (d), the material is an inorganic nonmetal material in a slurry state, and the slurry state inorganic nonmetal material is obtained by mixing the inorganic nonmetal material particles into a solvent.

14. The method of claim 1, wherein in step (d), the material is an inorganic nonmetal material in gaseous state, and the gaseous state inorganic nonmetal material is obtained by a method of sputtering, chemical vapor deposition, physical deposition or thermal evaporation.

15. The method of claim 1, wherein in step (d), the material is a polymer material.

16. The method of claim 15, wherein the polymer material is a liquid state thermosetting polymer, and step (d) further comprises substeps of:
(d1) providing a die and the liquid state thermosetting polymer, and placing the carbon nanotube structure in the die;
(d2) injecting the liquid state thermosetting polymer into the die to obtain a carbon nanotube composite preform; and
(d3) solidifying the liquid state thermosetting polymer.

17. The method of claim 16, wherein step (d1) further comprises substeps of:
(d11) providing a polymer, and heating and agitating the polymer at a temperature of less than or equal to 300° C.; and
(d12) adding at least one additive into the polymer.

18. The method of claim 16, wherein (d3) comprises substeps of:
(d31) heating the carbon nanotube composite preform to a predetermined temperature and maintaining the predetermined temperature for a period of time; and
(d32) cooling the carbon nanotube composite preform.

19. A method for making a planar heater, the method comprising the following steps:
(a) providing a planar supporter, a carbon nanotube structure, a first electrode and a second electrode;
(b) fixing the carbon nanotube structure on a surface of the planar supporter;
(c) connecting the first and the second electrodes to the carbon nanotube structure; and
(d) supplying a material into the carbon nanotube structure to achieve a carbon nanotube composite structure.

20. A method for making a planar heater, the method comprising the following steps:
(a) providing a linear carbon nanotube structure, a planar supporter and two electrodes;
(b) arranging the linear carbon nanotube structure on the planar supporter in such a manner that the linear carbon nanotube structure serpentinely defines a plane;
(c) separately connecting the two electrodes with two ends of the linear carbon nanotube structure; and
(d) supplying a material to the linear carbon nanotube structure to achieve a linear carbon nanotube composite structure.
